(19) United States
(12) Patent Application Publication
(10) Pub. No.: US 2024/0404918 A1
(43) Pub. Date: Dec. 5, 2024

(54) SEMICONDUCTOR DEVICE AND METHOD FOR MANUFACTURING THE SAME

(71) Applicant: Samsung Electronics Co., Ltd., Suwon-si (KR)

(72) Inventors: Joong Suk OH, Suwon-si (KR); Ho Young KIM, Suwon-si (KR); Ki Ho BAE, Suwon-si (KR)

(21) Appl. No.: 18/397,367

(22) Filed: Dec. 27, 2023

(30) Foreign Application Priority Data
May 31, 2023 (KR) 10-2023-0069726

(51) Int. Cl. H01L 23/48; H01L 21/762; H01L 29/06

(52) U.S. Cl. CPC H01L 23/481; H01L 21/76224; H01L 29/0673; H01L 29/0696

(57) ABSTRACT

There is provided a semiconductor device in which thickness variation of a substrate is precisely controlled. The semiconductor device includes a substrate comprising cell regions, a dummy region between the cell regions, an upper surface and a lower surface opposite the upper surface in a first direction, an active pattern disposed on the upper surface of the substrate, the active pattern comprising a lower pattern extending in a second direction crossing the first direction and a plurality of sheet patterns spaced apart in the first direction from each other, the plurality of sheet patterns being disposed in the cell region, a source/drain pattern disposed between the gate structures adjacent to each other, and a buried insulating pattern penetrating the substrate and the lower pattern in the dummy region.

### CROSS-REFERENCE TO RELATED APPLICATION

This application claims priority to Korean Patent Application No. 10-2023-0069726 filed on May 31, 2023 in the Korean Intellectual Property Office, and all the benefits accruing therefrom under 35 U.S.C. 119, the contents of which in their entirety are herein incorporated by reference.

### BACKGROUND

### 1. Technical Field

The present disclosure relates to a semiconductor device and a method for manufacturing the same.

### 2. Description of the Related Art

As semiconductor devices are miniaturized and become precise, precision is required in a process of etching a substrate. For example, it is important to planarize surfaces of substrates by etching the substrates.

For example, it is important to planarize both a front and a backside of the substrate. If the front and the backside are not flat, layers stacked on the substrate may not be properly aligned. Accordingly, processes have been developed for more precise control of thickness variation of the substrates during the process of planarizing the substrates.

### SUMMARY

Aspects of the present disclosure provide a semiconductor device in which thickness variation of a substrate is precisely controlled.

Aspects of the present disclosure also provide a method for manufacturing a semiconductor device in which thickness variation of a substrate is precisely controlled.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising a substrate comprising cell regions, a dummy region between the cell regions, an upper surface, and a lower surface opposite the upper surface in a first direction, an active pattern disposed on the upper surface of the substrate, the active pattern comprising a lower pattern extending in a second direction crossing the first direction and a plurality of sheet patterns spaced apart from each other in the first direction, the plurality of sheet patterns being disposed in the cell region, a plurality of gate structures spaced apart from each other in the second direction on the lower pattern, the plurality of gate structures comprising a gate electrode and a gate insulating layer, the gate electrode and the gate insulating layer surrounding the sheet patterns, a source/drain pattern disposed between the gate structures adjacent to each other, and a buried insulating pattern penetrating the substrate and the lower pattern in the dummy region, wherein the buried insulating pattern comprises a first surface and a second surface opposite to each other in the first direction, the first surface of the buried insulating pattern is placed on the same plane as the lower surface of the substrate, and the second surface of the buried insulating pattern is higher than the upper surface of the substrate.

According to another aspect of the present disclosure, there is provided a semiconductor device comprising a substrate comprising a cell region. a dummy region adjacent to the cell region, an upper surface, and a lower surface opposite the upper surface in a first direction, an active pattern disposed on the upper surface of the substrate, the active pattern comprising a lower pattern extending in a second direction crossing the first direction and a plurality of sheet patterns spaced apart from each other in the first direction, the plurality of sheet patterns being disposed in the cell region, a plurality of gate structures spaced apart from each other in the second direction on the lower pattern, the plurality of gate structures comprising a gate electrode and a gate insulating layer, the gate electrode and the gate insulating layer surrounding the sheet patterns, a source/drain pattern disposed between the gate structures adjacent to each other, and a buried insulating pattern penetrating the substrate and the lower pattern in the dummy region, wherein the buried insulating pattern comprises a first surface and a second surface opposite to each other in the first direction, the first surface of the buried insulating pattern is on the same plane as the lower surface of the substrate, and the second surface of the buried insulating pattern is higher than the upper surface of the substrate.

According to still another aspect of the present disclosure, there is provided a method of manufacturing a semiconductor device, comprising providing a substrate comprising a cell region and a dummy region, forming a lower pattern on an upper surface of the substrate, forming an upper pattern comprising sacrificial patterns and active patterns alternately disposed on an upper surface of the lower pattern, forming a trench penetrating the lower pattern and the upper pattern, filling the trench with a field insulating layer, forming a mask pattern on the upper pattern, forming a buried insulating pattern penetrating the mask pattern, the upper pattern, and the lower pattern in the dummy region, a lower surface of the buried insulating pattern being lower than the upper surface of the substrate, and an upper surface of the buried insulating pattern and an upper surface of the upper pattern being disposed on the same plane, and recessing the buried insulating pattern to form a buried pattern up to the same plane as the upper surface of the lower pattern.

### BRIEF DESCRIPTION OF THE DRAWINGS

The above and other aspects and features of the present disclosure will become more apparent by describing in detail example embodiments thereof with reference to the attached drawings, in which:

FIG. 1 is a schematic layout diagram of the present disclosure;

FIG. 2 is a cross-sectional view taken along line A-A of FIG. 1;

FIGS. 3 and 4 are cross-sectional views taken along line B-B of FIG. 1 according to some embodiments of the present disclosure, respectively;

FIG. 5 is a cross-sectional view taken along line C-C of FIG. 1;

FIG. 6 is a cross-sectional view taken along line B-B of FIG. 1 according to some embodiments of the present disclosure;

FIG. 7 is a cross-sectional view taken along line B-B of FIG. 1 according to some embodiments of the present disclosure;

FIGS. 8 to 44 are diagrams for describing a method for manufacturing a semiconductor device according to some embodiments of the present disclosure.

### DETAILED DESCRIPTION OF THE EMBODIMENTS

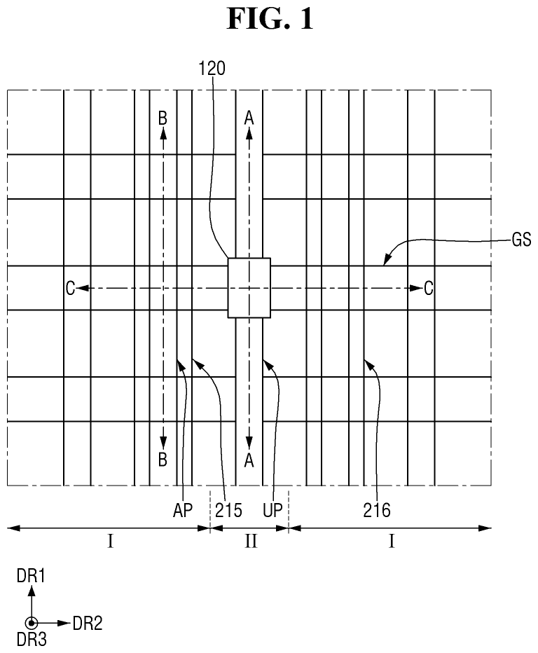

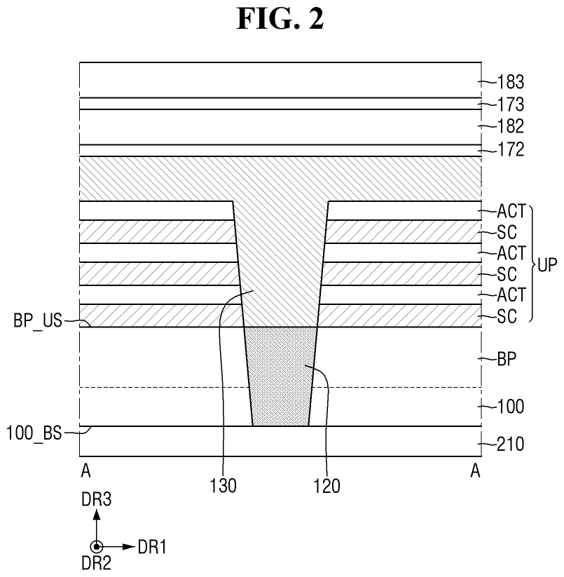

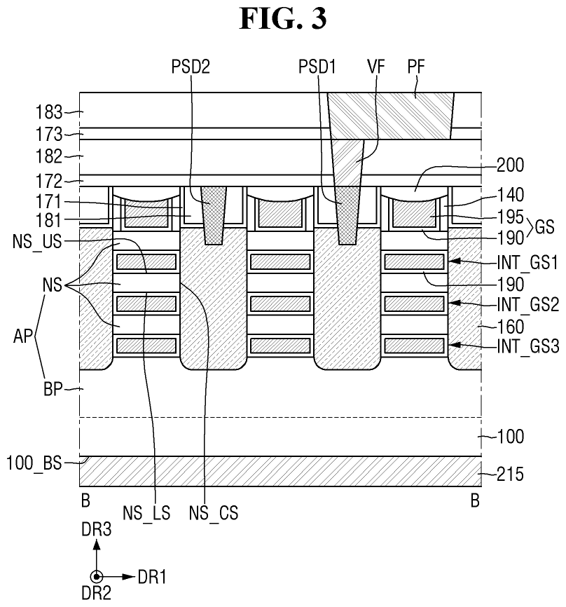

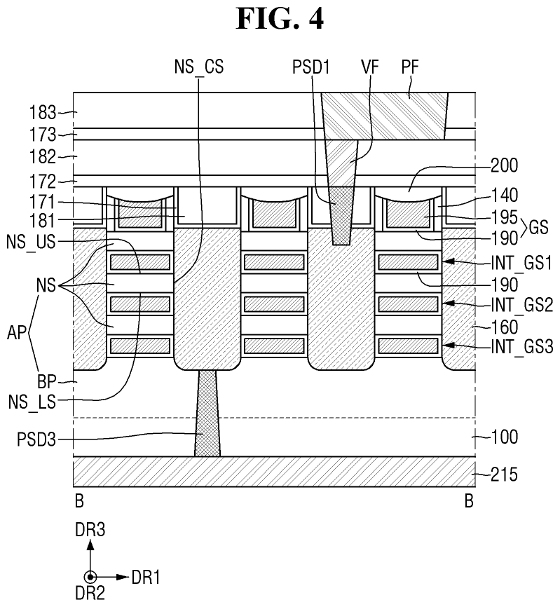

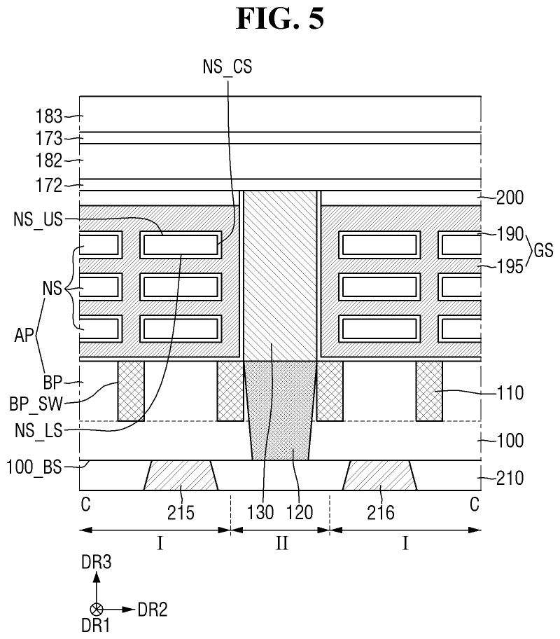

FIG. 1 is a schematic layout diagram of the present disclosure. FIG. 2 is a cross-sectional view taken along line A-A of FIG. 1. FIGS. 3 and 4 are cross-sectional views taken along line B-B of FIG. 1 according to some embodiments of the present disclosure, respectively. FIG. 5 is a cross-sectional view taken along line C-C of FIG. 1.

In FIG. 1, a semiconductor device is briefly illustrated except a first source/drain contact PSD1, a first etch stop layer 171, a first interlayer insulating layer 181, and the like.

Referring to FIGS. 1 to 5, a semiconductor device according to some embodiments may include a buried insulating pattern 120, a source/drain pattern 160, a first backside wiring line 215, a second backside wiring line 216, and a gate structure GS.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The substrate 100 may be a bulk silicon or silicon-on-insulator (SOI) substrate. Alternatively, the substrate 100 may be a silicon substrate, or may include other materials such as silicon germanium, silicon germanium on insulator (SGOI), indium antimonide, a lead tellurium compound, indium arsenide, indium phosphide, gallium arsenide, or gallium antimonide, but is not limited thereto.

The substrate 100 may include a cell region I and a dummy region II between cell regions I. Structures such as the gate structure GS, the source/drain pattern 160, an active pattern AP, and the like may be formed in the cell region I of the substrate 100. For example, the active pattern AP and the gate structure GS may be disposed in the cell region I of the substrate 100. On the contrary, the structures such as the gate structure GS, the source/drain pattern 160, the active pattern AP, and the like may not be formed in the dummy region II of the substrate 100. For example, the active pattern AP and the gate structure GS may not be disposed in the dummy region II of the substrate 100.

Each active pattern AP may be disposed on the substrate 100. The active pattern AP may be elongated (e.g., extend lengthwise) in a first direction DR1. The active pattern AP may be formed in the cell region I of the substrate 100.

The active patterns AP may be spaced apart from each other in a second direction DR2. For example, the first direction DR1 is a direction crossing (e.g., perpendicular to) the second direction DR2. Neighboring active patterns AP are adjacent to each other in the second direction DR2.

For example, PMOS transistors may be formed on some active patterns AP, and NMOS transistors may be formed on some other active patterns AP. For another example, NMOS transistors may be formed on all active patterns AP. For still another example, PMOS transistors may be formed on all active patterns AP.

The active pattern AP may be a multi-channel active pattern. The active pattern AP may include a lower pattern BP and a plurality of sheet patterns NS.

The lower pattern BP may protrude from the substrate 100. The lower pattern BP may be elongated (e.g., extend lengthwise) in the second direction DR2.

Neighboring lower patterns BP may be spaced apart from each other in the first direction DR1. The lower patterns BP may be separated by a fin trench extending (e.g., lengthwise) in the first direction DR1.

The plurality of sheet patterns NS may be disposed on the lower pattern BP. Each sheet pattern NS may include a plurality of nanosheets sequentially disposed (e.g., overlapping) in a third direction DR3.

Each sheet pattern NS may be spaced apart from the lower pattern BP in the third direction DR3. The plurality of sheet patterns NS spaced apart from each other may be arranged (e.g., spaced apart) in the first direction DR1 along an upper/top surface BP_US of the lower pattern BP.

Spatially relative terms, such as “beneath,” “below,” “lower,” “above,” “upper,” “top,” “bottom” and the like, may be used herein for ease of description to describe positional relationships as illustrated in the figures. It will be understood that the spatially relative terms encompass different orientations of the device in addition to the orientation depicted in the figures.

A third direction DR3 may intersect (e.g., perpendicular to) the first direction DR1 and the second direction DR2. For example, the third direction DR3 may be a thickness direction of the substrate 100. The first direction DR1 may be a direction crossing (e.g., perpendicular to) the second direction DR2.

An upper/top surface NS_US and a lower/bottom surface NS_LS of each sheet pattern NS may be connected by a connection surface NS_CS of the sheet pattern NS. The connection surface NS_CS of the sheet pattern NS is connected to and in contact with the source/drain pattern 160 to be described later. The connection surface NS_CS of the sheet pattern NS may be the boundary surface between the sheet pattern NS and the source/drain pattern 160.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact. Other words used to describe the relationship between elements should be interpreted in a like fashion (e.g., “between” versus “directly between,” “adjacent” versus “directly adjacent,” etc.).

Although it is illustrated that three sheet patterns NS are arranged in the third direction DR3 in the figures, this is merely for simplicity of description and the present disclosure is not limited thereto.

Each lower pattern BP may be formed by etching a portion of the substrate 100, or may include an epitaxial layer grown from the substrate 100. Each lower pattern BP may include silicon or germanium, each of which is an elemental semiconductor material. In certain embodiments, each lower pattern BP may include a compound semiconductor, for example, a group IV-IV compound semiconductor or a group III-V compound semiconductor.

The group IV-IV compound semiconductor may be a binary compound or a ternary compound including at least two elements selected from the group consisting of carbon (C), silicon (Si), germanium (Ge) and tin (Sn), or the above-mentioned compound doped with a group IV element.

The group III-V compound semiconductor may be, for example, a binary compound, a ternary compound or a quaternary compound formed by combining at least one of aluminum (Al), gallium (Ga) and indium (In) which are group III elements with one of phosphorus (P), arsenic (As) and antimonium (Sb) which are group V elements.

Each sheet pattern NS may include one of silicon or germanium, which is an elemental semiconductor material, a group IV-IV compound semiconductor, or a group III-V compound semiconductor.

Each sheet pattern NS may include or be formed of the same material as the lower pattern BP, or may include or be formed of a material different from that of the lower pattern BP.

In the semiconductor device according to some embodiments, the lower pattern BP may be a silicon lower pattern containing silicon, and the sheet pattern NS may be a silicon sheet pattern containing silicon.

The width of the sheet pattern NS in the second direction DR2 may increase or decrease in proportion to the width of the lower pattern BP in the second direction DR2. In one example, although it is illustrated that the widths in the second direction DR2 of the sheet patterns NS stacked in the third direction DR3 are the same, this is merely for simplicity of description, and the present disclosure is not limited thereto. Unlike the illustrated examples, the width in the second direction DR2 of the sheet patterns NS stacked in the third direction DR3 may decrease as the distance from the lower pattern BP increases. For example, among the sheet patterns NS stacked in the third direction DR3, a first sheet pattern NS closer to the lower pattern BP than a second sheet pattern NS may have a width in the second direction DR2 smaller than a width of the second sheet pattern NS in the second direction DR2 in certain embodiments.

The field insulating layer 110 may be formed on the substrate 100. The field insulating layer 110 may be disposed on the sidewall of the lower pattern BP. The field insulating layer 110 may be disposed between the adjacent lower patterns BP. The field insulating layer 110 may cover/contact the sidewalls of the lower patterns BP. The field insulating layer 110 may not be disposed on the upper surface BP_US of the lower pattern BP.

For example, the field insulating layer 110 may entirely cover the sidewalls of the lower patterns BP. Unlike the illustrated examples in the figures, the field insulating layer 110 may cover/contact a portion of the sidewall of the lower pattern BP in certain embodiments. In this case, a portion of the lower pattern BP may protrude from the upper surface of the field insulating layer 110 in the third direction DR3.

Each sheet pattern NS is disposed higher than the upper surface of the field insulating layer 110. The field insulating layer 110 may include or be formed of, for example, an oxide layer, a nitride layer, an oxynitride layer, or a combination layer thereof. Although the field insulating layer 110 is illustrated as being a single layer in the figures, this is only for simplicity of description, and the present disclosure is not limited thereto.

The gate structure GS may be disposed on the active pattern AP. The gate structure GS may cross the active pattern AP.

The gate structure GS may cross the lower pattern BP. The gate structure GS may surround each sheet pattern NS. The gate structure GS may include or be formed of, for example, a gate electrode 195 and a gate insulating layer 190.

Although it is illustrated that the gate structure GS is disposed over the active pattern AP in FIG. 1, this is merely for simplicity of description and the present disclosure is not limited thereto. For example, the gate structure GS may be separated into two parts, and the gate structures GS intersecting the active pattern AP may be spaced apart from each other in the second direction DR2, e.g., as shown in FIG. 5.

The gate structure GS may include inter-gate structures INT_GS1, INT_GS2, and INT_GS3 disposed between the sheet patterns NS adjacent in the third direction DR3 and between the lower pattern BP and a lowermost sheet pattern NS. The inter-gate structures INT_GS1, INT_GS2, and INT_GS3 may be disposed between the upper surface BP_US of the lower pattern BP and a lower/bottom surface NS_LS of a sheet pattern NS disposed at the lowermost position and between upper surfaces NS_US of sheet patterns NS and lower surfaces NS_LS of sheet patterns NS facing each other in the third direction DR3.

The number of inter-gate structures INT_GS1, INT_GS2, and INT_GS3 may be proportional to the number of sheet patterns NS included in the active pattern AP. For example, the number of inter-gate structures may be the same as the number of sheet patterns NS included in the active pattern AP. For example, when the number of sheet patterns NS is three, the gate structure GS may include (e.g., be formed of) first to third inter-gate structures INT_GS1, INT_GS2, and INT_GS3. Since the active pattern AP includes the plurality of sheet patterns NS, the gate structure GS may include the plurality of inter-gate structures INT_GS1, INT_GS2, and INT_GS3.

In a semiconductor device according to some embodiments, the inter-gate structures INT_GS1, INT_GS2, and INT_GS3 may be in contact with the source/drain pattern 160 to be described later. The inter-gate structures INT_GS1, INT_GS2, and INT_GS3 may be in contact with the upper surface BP_US of the lower pattern BP, the upper surfaces NS_US of the sheet patterns NS, and the lower surfaces NS_LS of the sheet patterns NS.

The following description will be made using the case where the number of inter-gate structures INT_GS1, INT_GS2, and INT_GS3 is three.

The gate structure may include the first inter-gate structure INT_GS1, the second inter-gate structure INT_GS2, and the third inter-gate structure INT_GS3. The first inter-gate structure INT_GS1, the second inter-gate structure INT_GS2, and the third inter-gate structure INT_GS3 may be sequentially disposed on the lower pattern BP. For example, the first to third inter-gate structures INT_GS1, INT_GS2 and INT_GS3 may be vertically overlap the lower pattern BP.

The third inter-gate structure INT_GS3 may be disposed between the lower pattern BP and the lowermost sheet pattern NS. The third inter-gate structure INT_GS3 may be disposed at the lowermost position among the inter-gate structures INT_GS1, INT_GS2, and INT_GS3. The third inter-gate structure INT_GS3 may be in contact with the upper surface BP_US of the lower pattern BP.

The first inter-gate structure INT_GS1 and the second inter-gate structure INT_GS2 may be disposed between the sheet patterns NS adjacent in the third direction DR3. The first inter-gate structure INT_GS1 may be disposed at the uppermost position among the inter-gate structures INT_GS1, INT_GS2, and INT_GS3. The first inter-gate structure INT_GS1 may be in contact with the lower surface NS_LS of the sheet pattern NS disposed at the uppermost position. The second inter-gate structure INT_GS2 may be disposed between the first inter-gate structure INT_GS1 and the third inter-gate structure INT_GS3.

The inter-gate structures INT_GS1, INT_GS2, and INT_GS3 may include the gate electrode 195 and the gate insulating layer 190 disposed between adjacent sheet patterns NS and between the lower pattern BP and the lowermost sheet pattern NS.

In a semiconductor device according to some embodiments, the first to third inter-gate structures INT_GS1, INT_GS2, and INT_GS3 may have the same width in the first direction DR1. The width of each of the first to third inter-gate structures INT_GS1, INT_GS2, and INT_GS3 in the first direction DR1 may be the same as the width of the first sheet pattern NS in the first direction DR1. However, the present disclosure is not limited thereto.

Unlike the illustrated examples of the drawings, in a semiconductor device according to some embodiments, the width of the third inter-gate structure INT_GS3 in the first direction DR1 may be greater than the width of an adjacent inter-gate structure (for example, the second inter-gate structure INT_GS2) in the first direction DR1.

The gate electrode 195 may be formed on the lower pattern BP. The gate electrode 195 may intersect the lower pattern BP, e.g., in a plan view. The gate electrode 195 may surround the sheet patterns NS.

A portion of the gate electrode 195 may be disposed between adjacent sheet patterns NS and between the lower pattern BP and the lowest sheet pattern NS. When the sheet patterns NS includes a first sheet pattern and a second sheet pattern adjacent to each other in the third direction DR3, a portion of the gate electrode 195 may be disposed between the upper surface of the first sheet pattern and the lower surface of the second sheet pattern facing each other. Further, a portion of the gate electrode 195 may be disposed between the upper surface BP_US of the lower pattern BP and the lower surface NS_LS of the sheet pattern NS disposed at the lowermost position. The first sheet pattern may be the sheet pattern NS disposed at the lowermost position or may not be the sheet pattern NS disposed at the lowermost position. Further, a portion of the gate electrode 195 may be disposed between a gate capping layer 200 to be described later and an uppermost sheet pattern NS disposed at the uppermost position among the sheet patterns NS stacked/overlapping in the third direction.

The gate electrode 195 may include or be formed of at least one of a metal, a metal alloy, a conductive metal nitride, a metal silicide, a doped semiconductor material, a conductive metal oxide, or a conductive metal oxynitride. The gate electrode 195 may include or be formed of, for example, at least one selected from the group consisting of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) and a combination thereof. The conductive metal oxide and the conductive metal oxynitride may include or may be a material which the above-mentioned material is oxidized, but are not limited thereto.

The gate electrodes 195 may be disposed on both sides of the source/drain pattern 160 to be described later. The gate structures GS may be disposed on both/opposite sides of the source/drain pattern 160 in the first direction DR1.

For example, the gate electrodes 195 disposed on both/opposite sides of the source/drain pattern 160 may be normal gate electrodes used as gates of transistors. For another example, the gate electrode 195 disposed on one side of the source/drain pattern 160 may be used as a gate electrode of a transistor, but the gate electrode 195 disposed on the other side of the source/drain pattern 160 may be a dummy gate electrode DG.

The gate insulating layer 190 may extend along the upper surface of the field insulating layer 110 and the upper surface BP_US of the lower pattern BP, e.g., in the second direction DR2. The gate insulating layer 190 may cover (e.g., contact) the sheet pattern NS. The gate insulating layer 190 may be disposed along the perimeter of the sheet pattern NS, e.g., in a cross-sectional view. The gate electrode 195 is disposed on (e.g., contact) the gate insulating layer 190.

A portion of the gate insulating layer 190 may be disposed between the sheet patterns NS adjacent in the third direction DR3 and between the lower pattern BP and the lowermost sheet pattern NS. When the sheet pattern NS includes the first sheet pattern and the second sheet pattern adjacent to each other, e.g., in the third direction, a portion of the gate insulating layer 190 may extend along the upper surface of the first sheet pattern and the lower surface of the second sheet pattern facing each other.

Although it is illustrated in the drawings that the gate insulating layer 190 is a single layer, the present disclosure is not limited thereto. The gate insulating layer 190 may include or be formed of an interface insulating layer and a high-k insulating layer. The interface insulating layer may be disposed between the high-k insulating layer and the sheet pattern NS.

The gate insulating layer 190 may include or be formed of silicon oxide, silicon oxynitride, silicon nitride, or a high-k material having a higher dielectric constant than silicon oxide. The high-k material may include or be formed of, for example, at least one selected from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The semiconductor device according to some embodiments may include a negative capacitor (NC) FET using a negative capacitor (NC). For example, the gate insulating layer 190 may include a ferroelectric material layer having ferroelectric properties and a paraelectric material layer having paraelectric properties.

The ferroelectric material layer may have a negative capacitance, and the paraelectric material layer may have a positive capacitance. For example, when two or more capacitors are connected in series and the capacitance of each capacitor has a positive value, the total capacitance becomes smaller than the capacitance of each capacitor. On the other hand, when at least one of the capacitances of two or more capacitors connected in series has a negative value, the total capacitance of the two or more capacitors may have a positive value and may be greater than the absolute value of each of the capacitances of the two or more capacitors.

When a ferroelectric material layer having a negative capacitance and a paraelectric material layer having a positive capacitance are connected in series, the total capacitance value of the ferroelectric material layer and the paraelectric material layer connected in series may increase. By using the principle that the total capacitance value is increased, the transistor containing the ferroelectric material layer may have a subthreshold swing (SS) lower than or equal to a threshold voltage lower than 60 mV/decade at room temperature.

The ferroelectric material layer may have ferroelectric properties. The ferroelectric material layer may include or be formed of, for example, at least one of hafnium oxide, hafnium zirconium oxide, barium strontium titanium oxide, barium titanium oxide, or lead zirconium titanium oxide. In this case, as one example, the hafnium zirconium oxide may be a material containing hafnium oxide doped with zirconium (Zr). As another example, the hafnium zirconium oxide may be a compound of hafnium (Hf), zirconium (Zr), and oxygen (O).

The ferroelectric material layer may further include a dopant doped therein. For example, the dopant may include or be formed of at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The type of dopant included in the ferroelectric material layer may vary depending on the ferroelectric material included in the ferroelectric material layer.

When the ferroelectric material layer includes hafnium oxide, the dopant included in the ferroelectric material layer may include or be formed of, for example, at least one of gadolinium (Gd), silicon (Si), zirconium (Zr), aluminum (Al), and yttrium (Y).

When the dopant is aluminum (Al), the ferroelectric material layer may include 3 to 8 atomic percent (at %) of aluminum. For example, the number of aluminum atoms may be 3 to 8 percent of the total number of atoms of the ferroelectric material layer. For example, the ratio of the dopant in the ferroelectric material layer may be from about 12.5 to about 33.5. In this case, the ratio of the dopant may be a ratio of aluminum to the sum of hafnium and aluminum.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

When the dopant is silicon (Si), the ferroelectric material layer may include 2 to 10 at % of silicon. For example, the number of silicon atoms may be 2 to 10 percent of the total number of atoms of the ferroelectric material layer. When the dopant is yttrium (Y), the ferroelectric material layer may include 2 to 10 at % of yttrium. For example, the number of yttrium atoms may be 2 to 10 percent of the total number of atoms of the ferroelectric material layer. When the dopant is gadolinium (Gd), the ferroelectric material layer may include 1 to 7 at % of gadolinium. For example, the number of gadolinium atoms may be 1 to 7 percent of the total number of atoms of the ferroelectric material layer. When the dopant is zirconium (Zr), the ferroelectric material layer may include 50 to 80 at % of zirconium. For example, the number of zirconium atoms may be 1 to 7 percent of the total number of atoms of the ferroelectric material layer.

The paraelectric material layer may have paraelectric properties. The paraelectric material layer may include or be formed of, for example, at least one of silicon oxide or metal oxide having a high dielectric constant. The metal oxide included in the paraelectric material layer may include or be formed of, for example, at least one of hafnium oxide, zirconium oxide, and aluminum oxide, but is not limited thereto.

The ferroelectric material layer and the paraelectric material layer may include the same material. The ferroelectric material layer may have ferroelectric properties, but the paraelectric material layer may not have ferroelectric properties. For example, when the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness that exhibits ferroelectric properties. The thickness of the ferroelectric material layer may be, for example, in a range of 0.5 nm to 10 nm, but is not limited thereto. Since a critical thickness at which each ferroelectric material exhibits ferroelectric properties may be different from others, the thickness of the ferroelectric material layer may vary depending on the ferroelectric material.

In one example, the gate insulating layer 190 may include one ferroelectric material layer. In another example, the gate insulating layer 190 may include a plurality of ferroelectric material layers spaced apart from each other. The gate insulating layer 190 may have a laminated layer structure in which a plurality of ferroelectric material layers and a plurality of paraelectric material layers are alternately stacked/laminated.

The gate capping layer 200 may be disposed on a gate spacer 140, the gate electrode 195, and the gate insulating layer 190. For example, the gate capping layer 200 may vertically overlap and contact the gate spacer 140, the gate electrode 195, and the gate insulating layer 190. The gate capping layer 200 may extend along the upper surface of the gate electrode 195. For example, the gate capping layer 200 may extend (e.g., lengthwise) in the second direction DR2. The gate capping layer 200 may cover/contact the upper surface of the gate electrode 195.

The gate capping layer 200 may cover the upper surface of the gate spacer 140. For example, the gate capping layer 200 may be in contact with the upper surface of the gate spacer 140. The sidewall of the gate capping layer 200 may be in contact with the first etch stop layer 171. For example, the gate spacer 140 may not be disposed between the sidewall of the gate capping layer 200 and the first etch stop layer 171.

The gate capping layer 200 may include or be formed of, for example, at least one of silicon oxide (SiO₂), silicon nitride (SiN), silicon oxynitride (SiON), silicon carbonitride (SiCN), silicon oxycarbonitride (SiOCN), silicon oxycarbide (SiOC), and a combination thereof.

The upper surface of the gate spacer 140 may be in contact with the gate capping layer 200.

The gate spacer 140 may include or be formed of, for example, at least one of silicon nitride (SiN), silicon oxynitride (SiON), silicon oxide (SiO₂), silicon oxynitride (SiOCN), silicon boron nitride (SiBN), silicon oxyboron nitride (SiOBN), silicon oxycarbide (SiOC) and a combination thereof. Although the gate spacer 140 is illustrated in the drawings as being a single layer, this is merely for simplicity of description and the present disclosure is not limited thereto.

The source/drain pattern 160 may be disposed on the active pattern AP.

The source/drain pattern 160 may be disposed on (e.g., contact) the lower pattern BP. The source/drain pattern 160 is connected to the sheet pattern NS. The source/drain pattern 160 is in contact with the sheet pattern NS. The source/drain pattern 160 may electrically connect the sheet patterns NS spaced apart in the first direction DR1.

As used herein, components described as being “electrically connected” are configured such that an electrical signal can be transferred from one component to the other (although such electrical signal may be attenuated in strength as it transferred and may be selectively transferred).

The source/drain pattern 160 may be disposed on at least one side of the gate structure GS. The source/drain pattern 160 may be disposed between the gate structures GS adjacent to each other in the first direction DR1. For example, the source/drain patterns 160 may be disposed on both sides of the gate structure GS (e.g., opposite in the first direction DR1). Unlike the illustrated examples in the drawings, the source/drain pattern 160 may be disposed on one side of the gate structure GS and may not be disposed on the other side of the gate structure GS.

The source/drain pattern 160 may be included in or may be a source/drain of a transistor using the sheet pattern NS as a channel region.

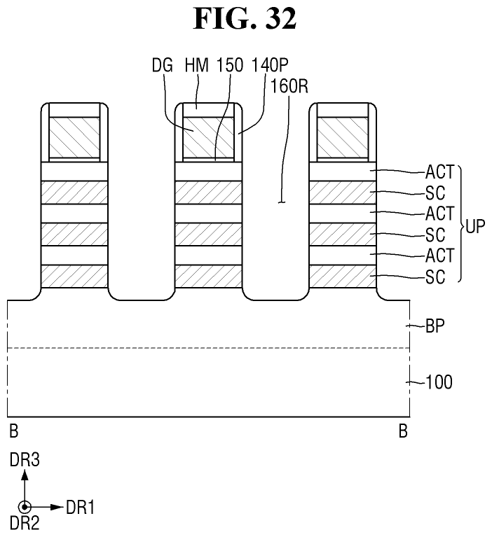

The source/drain pattern 160 may be disposed in a source/drain recess 160R (see FIG. 32). The source/drain recess 160R extends in the third direction DR3. The source/drain recess 160R may be defined between the gate structures GS adjacent to each other in the first direction DR1.

For example, the lower surface of the source/drain recess 160R may be defined by the lower pattern BP. The sidewall of the source/drain recess 160R may be defined by the sheet pattern NS and the inter-gate structures INT_GS1, INT_GS2, and INT_GS3. A portion of the sidewall of the source/drain recess 160R may be defined by the gate structure GS between the sheet pattern NS disposed at the uppermost position among the stacked sheet patterns NS in the third direction and the gate capping pattern. In a semiconductor device according to some embodiments, the sidewalls of the inter-gate structures INT_GS1, INT_GS2, and INT_GS3 may be defined by the gate insulating layers 190 of the inter-gate structures INT_GS1, INT_GS2, and INT_GS3.

Between the sheet pattern NS disposed at the lowermost position and the lower pattern BP, the boundary between the gate insulating layer 190 and the lower pattern BP may be the upper surface BP_US of the lower pattern BP. For example, the upper surface BP_US of the lower pattern BP may be the boundary between the third inter-gate structure INT_GS3 disposed at the lowermost position among the inter-gate structures and the lower pattern BP. The lower surface of the source/drain recess 160R is lower than the upper surface BP_US of the lower pattern BP.

The source/drain pattern 160 may be disposed in the source/drain recess 160R. The source/drain recess 160R may be filled, e.g., with the source drain/pattern 160.

The source/drain pattern 160 may be in contact with the sheet pattern NS and the lower pattern BP. The inter-gate structures INT_GS1, INT_GS2, and INT_GS3 may be in contact with the source/drain pattern 160. The gate structure GS may be in contact with the source/drain pattern 160. Unlike the illustrated examples in the drawings, when an inner spacer is disposed between the inter-gate structures INT_GS1, INT_GS2, and INT_GS3 and the source/drain pattern 160, the inter-gate structures INT_GS1, INT_GS2, and INT_GS3 may not be in contact with the source/drain pattern 160.

The source/drain pattern 160 may include or be formed of an epitaxial pattern. The source/drain pattern 160 includes or is formed of a semiconductor material.

The source/drain pattern 160 may include or be formed of, for example, silicon or germanium, which is an elemental semiconductor material. In certain embodiments, the source/drain pattern 160 may be formed of a binary compound or a ternary compound including at least two elements selected from the group consisting of carbon (C), silicon (Si), germanium (Ge) and tin (Sn), or the above-mentioned compound doped with a group IV element. For example, the source/drain pattern 160 may include or be formed of silicon, silicon-germanium, germanium, silicon carbide, or the like, but the present disclosure is not limited thereto.

The source/drain pattern 160 may include impurities doped into a semiconductor material. The doped impurities may include or be formed of at least one of boron (B), phosphorus (P), carbon (C), arsenic (As), antimony (Sb), bismuth (Bi), and oxygen (O), but are not limited thereto.

Although the source/drain pattern 160 is illustrated as being a single layer in the drawings, this is merely for simplicity of description and the present disclosure is not limited thereto.

Although it is illustrated in the drawings that the source/drain pattern 160 has the same width in the first direction DR1, the present disclosure is not limited thereto.

Unlike the illustrated examples, in a semiconductor device according to some embodiments, the width of the source/drain pattern 160 in the first direction DR1 may increase and then decrease as the distance from the lower pattern BP increases. For example, the widths of the source/drain pattern 160 in the first direction DR1 may be greater at a middle level than at an upper level (e.g., at a top) and at a lower level (e.g., at a bottom) of the source/drain pattern 160.

Unlike the illustrated examples, in a semiconductor device according to some embodiments, the width of the source/drain pattern 160 in the first direction DR1 may be greater than the width of the first etch stop layer 171 in the first direction DR1. Here, the width of the source/drain pattern 160 in the first direction DR1 may be the same as a width/distance between the sheet patterns NS directly adjacent to each other in the first direction DR1.

In a semiconductor device according to some embodiments, the upper surface of the source/drain pattern 160 may be higher than the upper surface of the sheet pattern NS disposed at the uppermost position. For example, from the upper surface BP_US of the lower pattern BP in the third direction, a distance to the upper surface of the source/drain pattern 160 may be greater than a distance to the upper surface of the sheet pattern NS disposed at the uppermost position. However, the present disclosure is not limited thereto. For example, the upper surface of the source/drain pattern 160 may be at the same level as or at a lower level than the upper surface of the sheet pattern NS disposed at the uppermost position.

The first etch stop layer 171 may extend along the sidewall of the gate capping layer 200, the upper surface of the field insulating layer 110, and the sidewall/profile of the source/drain pattern 160. The upper surface of the first etch stop layer 171 may be disposed on the same plane (e.g., at the same level) as the upper surface of the gate capping layer 200.

The first etch stop layer 171 may contain or be formed of a material having an etching selectivity with respect to the first interlayer insulating layer 181 to be described later. The first etch stop layer 171 may include or be formed of, for example, at least one of silicon nitride (SiN), silicon oxide (SiO₂), silicon oxynitride (SiON), silicon oxynitride (SiOCN), silicon boron nitride (SiBN), silicon oxyboron nitride (SiOBN), silicon oxycarbide (SiOC) and a combination thereof.

The first interlayer insulating layer 181 may be disposed on the first etch stop layer 171. The first interlayer insulating layer 181 may be disposed on the source/drain pattern 160. The first interlayer insulating layer 181 may not cover (e.g., may not vertically overlap) the upper surface of the gate capping layer 200 and the upper surface of the gate spacer 140. For example, the upper surface of the first interlayer insulating layer 181 may be disposed on the same plane (e.g., at the same level) as the upper surface of the gate capping layer 200.

The first interlayer insulating layer 181 may include or be formed of, for example, at least one of silicon oxide, silicon nitride, silicon oxynitride, and a low-k material. The low-k material may include or may be, for example, fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazene (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

The buried insulating pattern 120 may be formed in the dummy region II. The buried insulating pattern 120 may penetrate the substrate 100 and the lower pattern BP. The buried insulating pattern 120 may be in contact with a portion of the field insulating layer 110 existing/formed in the dummy region II.

The buried insulating pattern 120 may include an upper/top surface and a lower/bottom surface opposite to each other in the third direction DR3.

The upper surface of the buried insulating pattern 120 may be disposed on the same plane (e.g., at the same level) as the upper surface BP_US of the lower pattern BP. The upper surface of the buried insulating pattern 120 may be disposed on the same plane (e.g., at the same level) as the upper surface of the field insulating layer 110. The upper surface of the buried insulating pattern 120 may be higher than the upper surface of the substrate 100.

The lower surface of the buried insulating pattern 120 may be disposed on the same plane (e.g., at the same level) as a lower/bottom surface 100_BS of the substrate 100. The lower surface of the buried insulating pattern 120 may be disposed on the same plane (e.g., at the same level) as the upper surface of a backside wiring insulating layer 210 to be described later.

The buried insulating pattern 120 may include or be formed of at least one of silicon nitride (SiN), silicon oxide (SiO₂), and a combination thereof. The buried insulating pattern 120 may be an etch stop layer in the case of etching the lower surface 100_BS of the substrate 100.

By etching the substrate 100, the substrate 100 may be thinned. In the case of thinning the lower surface 100_BS of the substrate 100, if there is no etch stop layer, the thickness of the substrate 100 may vary depending on wafers. In addition, when there is no etch stop layer, there may be large variation in the thickness in one wafer. As the thickness variation of the substrate 100 increases, it may be difficult to deposit an insulating layer on the lower surface 100_BS of the substrate 100.

In a process of etching the lower surface 100_BS of the substrate 100, the buried insulating pattern 120 may serve as an etch stop layer. For example, if the buried insulating pattern 120 is exposed during a process of planarizing the lower surface 100_BS of the substrate 100, such as chemical mechanical polishing (CMP), the planarization process may be stopped. Accordingly, the thickness variation of the substrate 100 according to the position of the substrate 100 may be reduced.

A dummy blocking layer 130 may be formed in the dummy region II. The dummy blocking layer 130 may be in contact with the upper surface of the buried insulating pattern 120. The dummy blocking layer 130 may penetrate the gate capping layer 200 and the gate electrode 195. Although it is illustrated in the drawings that a portion of the gate insulating layer 190 extends along the sidewall of the dummy blocking layer 130, the present disclosure is not limited thereto. Unlike the illustrated examples the sidewall of the dummy blocking layer 130 may be in contact with the gate electrode 195 in certain embodiments.

Although it is illustrated that the dummy blocking layer 130 located in the dummy region II exists between the active patterns AP for simplicity of description, the present disclosure is not limited thereto. For example, an active pattern may exist in an area spaced apart from one sidewall of the dummy blocking layer 130, but an active pattern may not exist in an area spaced apart from the other sidewall of the dummy blocking layer 130 in certain embodiments.

Further, although it is illustrated that the distances from the dummy blocking layer 130 located in the dummy region II to neighboring active patterns AP are the same, the present disclosure is not limited thereto. For example, the distance from the dummy blocking layer 130 to the active pattern AP adjacent to one sidewall of the dummy blocking layer 130 and the distance from the dummy blocking layer 130 to the active pattern AP adjacent to the other sidewall of the dummy blocking layer 130 may be different.

The dummy blocking layer 130 may include or be formed of silicon oxide, silicon oxynitride, silicon nitride, or a high-k material having a higher dielectric constant than silicon oxide.

Another structure may not be disposed in the dummy region II due to the dummy blocking layer 130. For example, the gate structure GS or the source/drain pattern 160 may not be formed in the dummy region II.

On the contrary, at least one structure may be disposed in the cell region I where the dummy blocking layer 130 is not located. For example, the gate structure GS or the source/drain pattern 160 may be formed in the cell region I.

In this specification, it is illustrated that the dummy region II is disposed between the cell regions I, but the present disclosure is not limited thereto. For example, the cell region I may exist only on one side of the dummy region II, and the cell region I may not exist on the other side thereof. For another example, the dummy region II may be included in the peripheral area of the substrate 100.

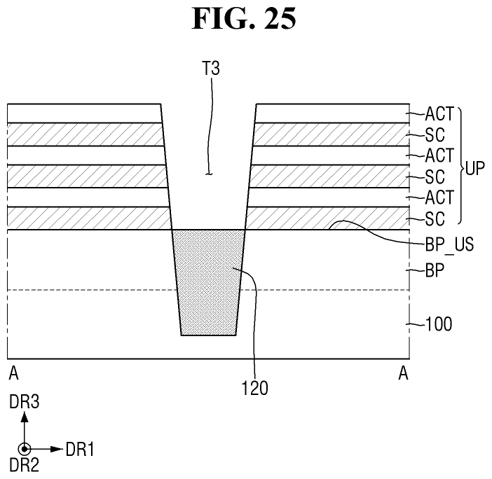

Referring back to FIG. 2, the dummy blocking layer 130 may surround an upper pattern UP. For example, the dummy blocking layer 130 may cover/contact the upper surface of the upper pattern UP, and may cover/contact the sidewall of the upper pattern UP exposed by the third trench T3 while filling a third trench T3 (see FIG. 25).

The dummy blocking layer 130 may extend along the first direction DR1. The width of the dummy blocking layer 130 in the second direction DR2 may be the same as the width of the buried insulating pattern 120 in the second direction DR2. The term “same” as used herein not only means being completely identical but also includes a minute difference that may occur due to a process margin or the like.

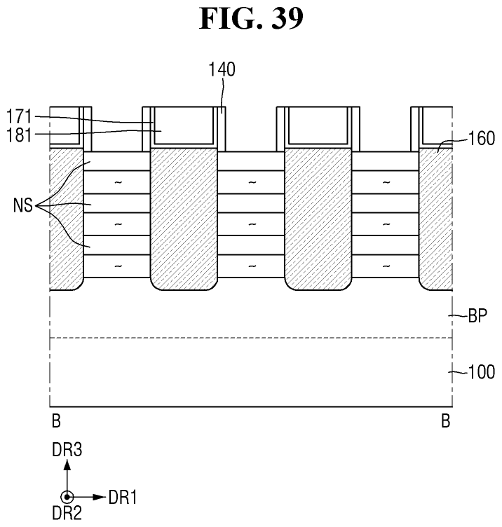

The upper pattern UP may be surrounded by the dummy blocking layer 130. A solution for performing wet etching may be added/applied to the substrate on which the upper pattern UP and the dummy blocking layer 130 during a process of removing a sacrificial pattern SC by wet etching (see FIG. 39). The solution for performing wet etching may not pass through the dummy blocking layer 130. Therefore, the sacrificial pattern SC of the upper pattern UP may not be removed at the region covered by the dummy blocking layer 130.

For example, even if a process of forming the sheet patterns NS by removing the sacrificial pattern SC in the cell region I proceeds, the active pattern ACT and the sacrificial pattern SC may remain/exist in the dummy region II due to the dummy blocking layer 130.

On the other hand, in FIGS. 3 and 4, the sacrificial pattern SC of the upper pattern UP may be removed, thereby forming the sheet patterns NS. Since the upper pattern UP where the sheet pattern NS is formed is not surrounded by the dummy blocking layer 130, the sacrificial pattern SC may be etched when the process of forming the sheet pattern NS proceeds.

For example, when the sacrificial pattern SC is removed from the cell region I, the sheet pattern NS may be formed by the removal of the sacrificial pattern SC from the cell region I.

In FIG. 5, the dummy blocking layer 130 may exist on the upper surface of the buried insulating pattern 120 in the dummy region II. Since the buried insulating pattern 120 occupies the dummy region II, the gate structure GS may not be formed in the dummy region II. On the other hand, the cell region I is not occupied by the dummy blocking layer 130, so that the sheet pattern NS and the gate structure GS may be formed in the cell region I.

The first source/drain contact PSD1 may be disposed on the source/drain pattern 160. The first source/drain contact PSD1 may penetrate the first etch stop layer 171 and the first interlayer insulating layer 181. The upper surface of the source/drain pattern 160 may be recessed by the first source/drain contact PSD1. The first source/drain contact PSD1 may be electrically connected to (e.g., contact) the source/drain pattern 160. The first source/drain contact PSD1 may be electrically connected to (e.g., contact) a front wiring via VF to be described later.

Although not shown, a silicide layer may be disposed between the first source/drain contact PSD1 and the source/drain pattern 160. The silicide layer may include or be formed of, for example, a metal silicide material.

In FIG. 3, a second source/drain contact PSD2 may be disposed on the source/drain pattern 160. The second source/drain contact PSD2 may penetrate the first etch stop layer 171 and the first interlayer insulating layer 181. The upper surface of the source/drain pattern 160 may be recessed by the second source/drain contact PSD2. The second source/drain contact PSD2 may be electrically connected to (e.g., contact) the source/drain pattern 160. The second source/drain contact PSD2 may not be electrically connected to a front wiring via VF to be described later.

Although not shown, a silicide layer may be disposed between the second source/drain contact PSD2 and the source/drain pattern 160. The silicide layer may include or be formed of, for example, a metal silicide material.

Although not shown, agate contact penetrating the gate capping layer 200 and electrically connected to (e.g., contact) the gate electrode 195 may be further included.

A second etch stop layer 172, a second interlayer insulating layer 182, a third etch stop layer 173, and a third interlayer insulating layer 183 may be sequentially stacked on the upper surface of the first source/drain contact PSD1, the upper surface of the second source/drain contact PSD2, and the upper surfaces of the gate capping layer 200 and the dummy blocking layer 130.

The front wiring via VF may be disposed on the first source/drain contact PSD1. The front wiring via VF may penetrate the second etch stop layer 172 and the second interlayer insulating layer 182. For example, a top surface of the front wiring via VF may be at the same level as a top surface of the second interlayer insulating layer 182 and a bottom surface of the front wiring via VF may be at the same level as a bottom surface of the second etch stop layer 172. The front wiring via VF may be electrically connected to (e.g., contact) the first source/drain contact PSD1.

A front wiring plug PF may be disposed on the front wiring via VF. The front wiring plug PF may penetrate the third etch stop layer 173 and the third interlayer insulating layer 183. For example, a top surface of the front wiring plug PF may be at the same level as a top surface of the third interlayer insulating layer 183 and a bottom surface of the front wiring plug PF may be at the same level as a bottom surface of the third etch stop layer 173. The front wiring plug PF may be electrically connected to (e.g., contact) the front wiring via VF.

In FIG. 4, a third source/drain contact PSD3 may be disposed under the source/drain pattern 160. The third source/drain contact PSD3 may penetrate the substrate 100 and the lower pattern BP. For example, atop surface of the third source/drain contact PSD3 may be at the same level as a top surface of the lower pattern BP and a bottom surface of the third source/drain contact PSD3 may be at the same level as a bottom surface of the substrate 100. The third source/drain contact PSD3 may be electrically connected to (e.g., contact) the source/drain pattern 160. The third source/drain contact PSD3 may be electrically connected to (e.g., contact) a backside wiring line to be described later.

Although not shown, a silicide layer may be disposed between the third source/drain contact PSD3 and the source/drain pattern 160. The silicide layer may include or be formed of, for example, a metal silicide material.

The backside wiring insulating layer 210 may be formed on the lower surface 100_BS of the substrate 100. The lower surface 100_BS of the substrate 100 may be in contact with the backside wiring insulating layer 210. The lower surface 100_BS of the substrate 100 may be on the same plane (e.g., at the same level) as the lower surface of the buried insulating pattern 120. For example, the lower surface 100_BS of the substrate 100 may be on the same plane (e.g., at the same level) as the upper surface of the backside wiring insulating layer 210.

The first backside wiring line 215 and the second backside wiring line 216 may be formed in the backside wiring insulating layer 210. The first backside wiring line 215 and the second backside wiring line 216 may be disposed on the lower surface 100_BS of the substrate 100. The first backside wiring line 215 and the second backside wiring line 216 may extend (e.g., lengthwise) in the first direction DR1. The first backside wiring line 215 and the second backside wiring line 216 may penetrate the backside wiring insulating layer 210 in the third direction DR3. The upper/top surface of the backside wiring line may be located on the same plane (e.g., at the same level) as the lower surface 100_BS of the substrate 100. A bottom surface of the backside wiring line may be at the same level as a bottom surface of the backside wiring insulating layer 210.

Each of the first source/drain contact PSD1, the second source/drain contact PSD2, the third source/drain contact PSD3, the front wiring via VF, and the front wiring plug PF may include or be formed of a conductive material, and may include or be formed of, for example, at least one of a metal nitride, a metal carbonitride, a two-dimensional (2D) material, and a conductive semiconductor material.

Although it is illustrated that each of the first source/drain contact PSD1, the second source/drain contact PSD2, and the third source/drain contact PSD3 is a single layer in the drawings, the present disclosure is not limited thereto. For example, at least one of the first source/drain contact PSD1, the second source/drain contact PSD2, and the third source/drain contact PSD3 may include or be formed of a contact barrier layer and a contact filling layer filling the space defined by the contact barrier layer.

The second interlayer insulating layer 182 and the third interlayer insulating layer 183 may include or be formed of, for example, at least one of silicon oxide, silicon nitride, silicon carbonitride, silicon oxynitride, and a low-k material.

The second etch stop layer 172 and the third etch stop layer 173 may include or be formed of, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), aluminum oxide (AlO), aluminum nitride (AlN) and aluminum oxycarbide (AlOC), and a combination thereof. The second etch stop layer 172 may include or be formed of, e.g., at least one of silicon oxide, silicon nitride, silicon carbonitride, silicon oxynitride, and a low-k material.

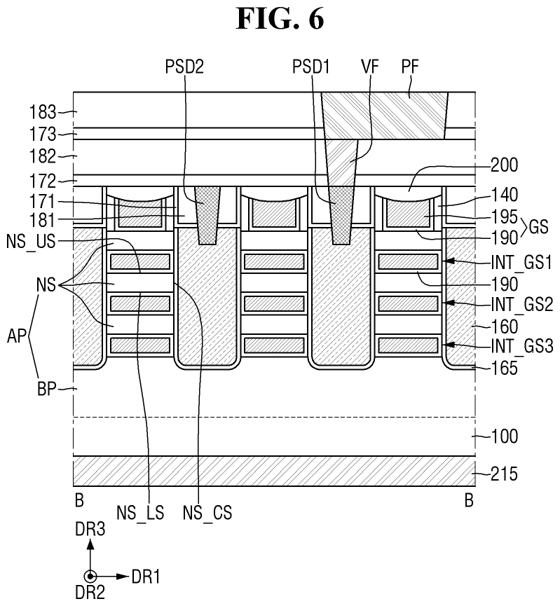

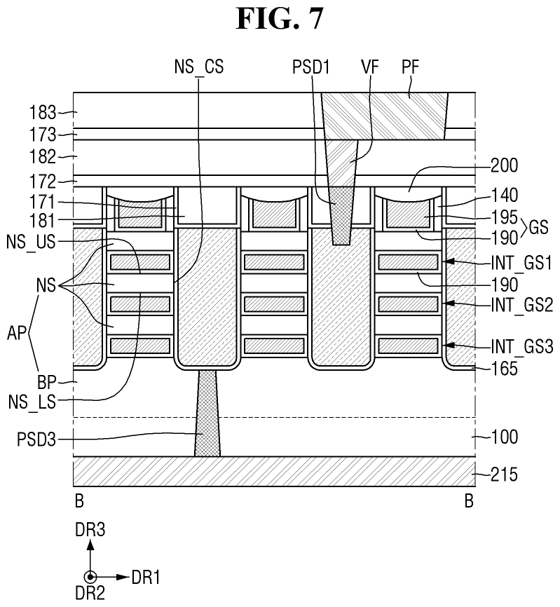

FIG. 6 is a cross-sectional view taken along line B-B of FIG. 1 according to some embodiments of the present disclosure. FIG. 7 is a cross-sectional view taken along line B-B of FIG. 1 according to some embodiments of the present disclosure. For simplicity of description, differences from FIGS. 1 to 5 will be mainly described with respect to FIGS. 6 and 7.

Referring to FIGS. 6 and 7, a semiconductor device according to some embodiments may include the source/drain capping layer 165 surrounding the source/drain pattern 160.

The source/drain capping layer 165 may be formed of a material in which silicon (Si) and carbon (C) or silicon germanium (SiGe) and carbon (C) are combined in a specific ratio. In FIG. 7, the source/drain capping layer 165 and the third source/drain contact PSD3 may be electrically connected to (e.g., contact) each other.

In a process of forming the gate electrode 195, the source/drain pattern 160 may be damaged. Since the source/drain capping layer 165 surrounds the source/drain pattern 160, damage to the source/drain pattern 160 may be minimized during the process of forming the gate electrode 195.

Although it is illustrated in the drawings that the source/drain capping layer 165 is a single layer, the present disclosure is not limited thereto. For example, the source/drain capping layer 165 may include or be formed of a source/drain blocking layer and a source/drain filling layer filling the space defined by the source/drain blocking layer. For example, the source/drain filling layer may be disposed on the source/drain blocking layer.

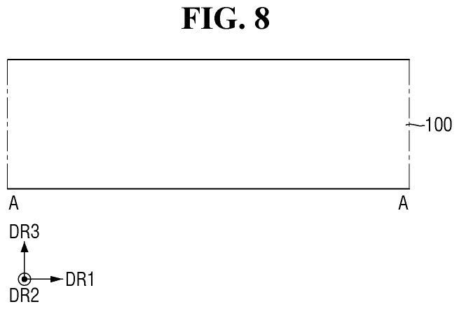

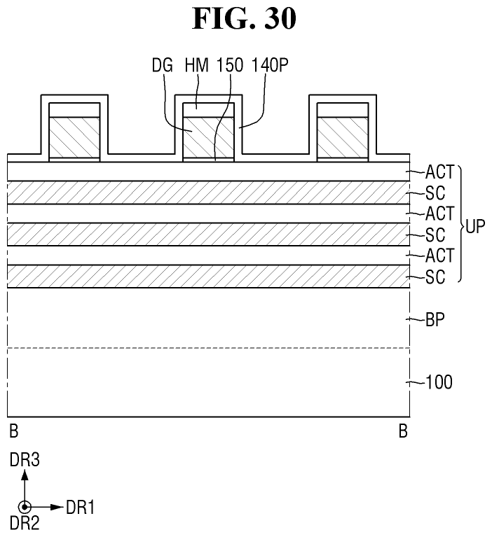

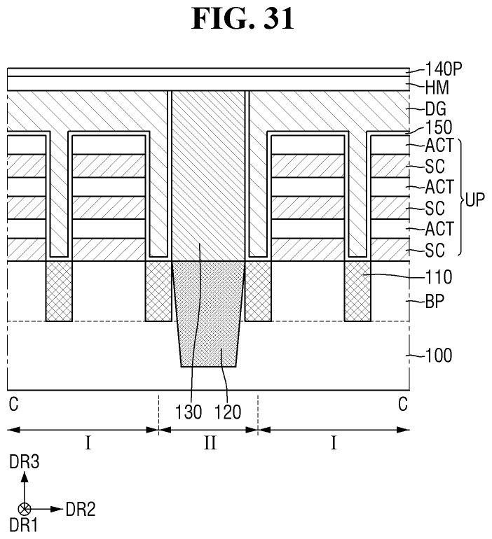

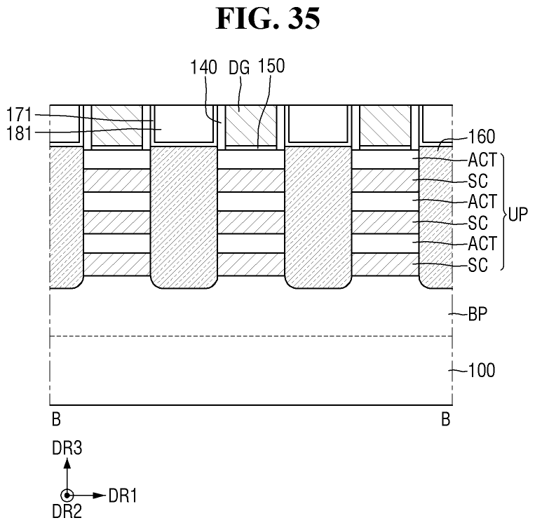

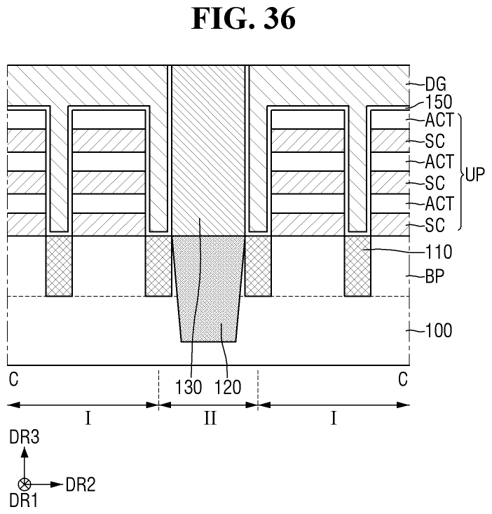

FIGS. 8 to 44 are diagrams for describing a method for manufacturing a semiconductor device according to some embodiments of the present disclosure.

FIGS. 8 to 44 illustrate a method for manufacturing a semiconductor device according to some embodiments of the present disclosure using cross-sectional views taken along lines A-A, B-B, and C-C of the layout diagram of FIG. 1.

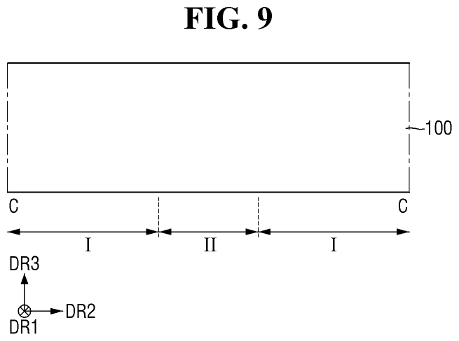

Referring to FIGS. 8 and 9, the substrate 100 is provided.

When at least a portion of the upper surface of the substrate 100 is etched, the lower pattern BP structure to be described later may be formed.

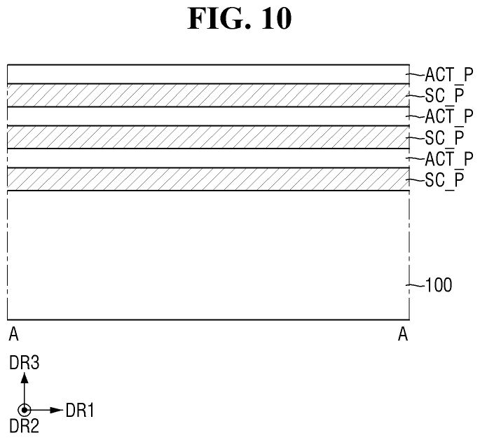

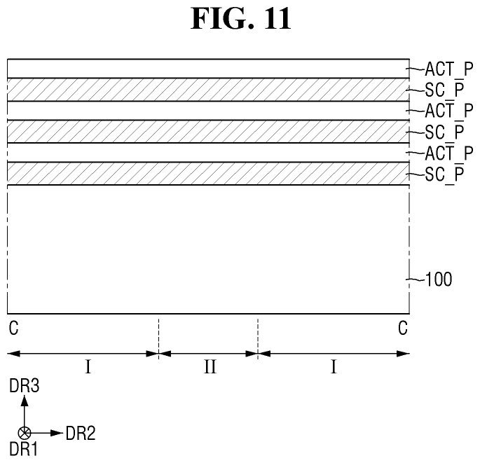

Referring to FIGS. 10 and 11, a pre-sacrificial pattern SC_P and a pre-active pattern ACT_P may be alternately stacked on the substrate 100.

For example, the pre-sacrificial pattern SC_P may include a silicon-germanium layer and/or may be formed of silicon-germanium layers. The pre-active pattern ACT_P may include a silicon layer and/or be formed of silicon layers.

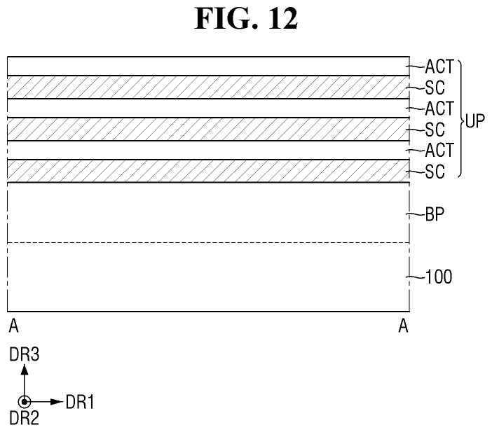

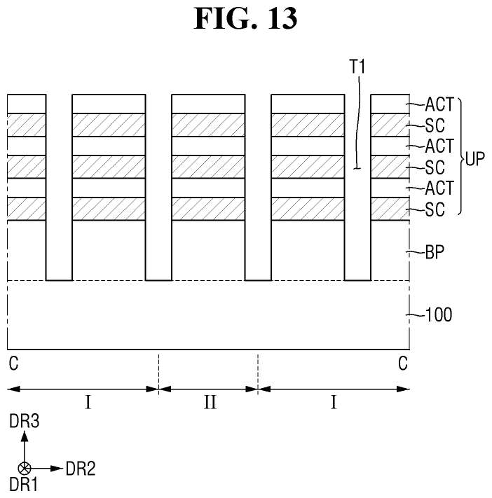

Referring to FIGS. 12 and 13, a first trench T1 may be formed.

A plurality of first trenches T1 may be spaced apart from each other in the second direction DR2. The first trench T1 may penetrate the pre-active pattern ACT_P and the pre-sacrificial pattern SC_P. A portion of the first trench T1 may be formed in the substrate 100. The lower surface of the first trench T1 may be placed in the substrate 100. The first trench T1 may extend in the third direction DR3. The first trench T1 may not be observed in the A-A cross section.

A portion of the substrate 100 is etched to form the first trench T1, thereby forming the lower pattern BP. The lower patterns BP may be spaced apart from each other in the second direction DR2.

The first trench T1 is formed, so that the upper pattern UP may be formed on the lower pattern BP. The upper pattern UP may include the active pattern ACT and the sacrificial pattern SC.

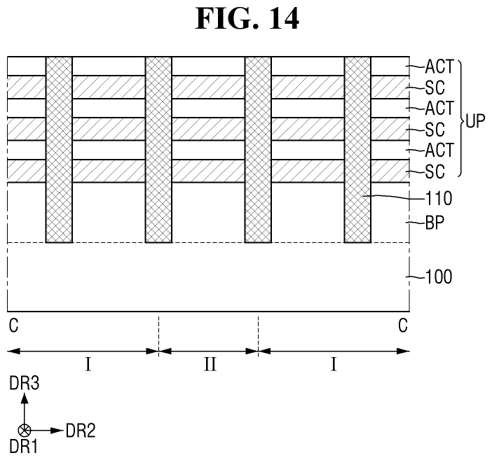

Referring to FIG. 14, the field insulating layer 110 may fill the first trench T1.

The field insulating layer 110 may be in contact with the lower pattern BP and the upper pattern UP. The upper surface of the field insulating layer 110 and the upper surface of the upper pattern UP may be on the same plane (e.g., at the same level).

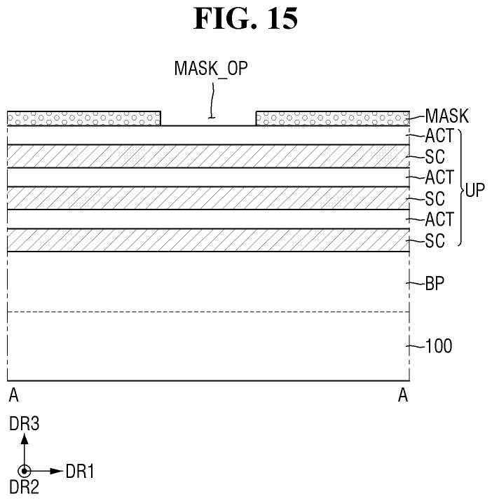

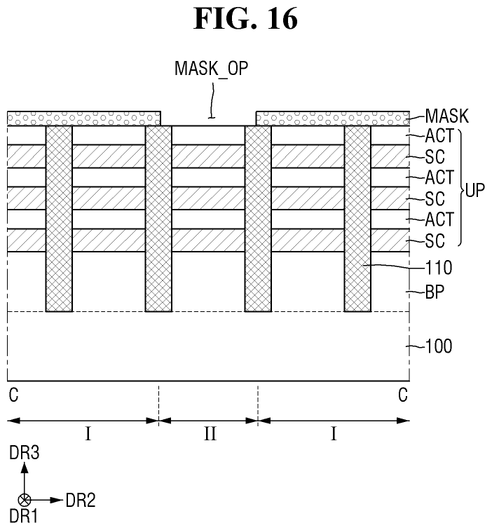

Referring to FIGS. 15 and 16, a mask pattern MASK may be formed on the upper pattern UP and the field insulating layer 110.

The mask pattern MASK may include an opening MASK_OP exposing a portion of the upper pattern UP.

The upper surface of the upper pattern UP may be covered by the mask pattern MASK. The upper surface of the field insulating layer 110 may be covered by the mask pattern MASK. The mask pattern MASK may include or be formed of silicon nitride (SiN).

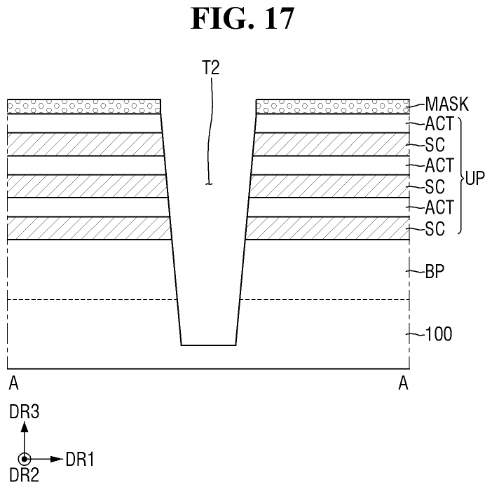

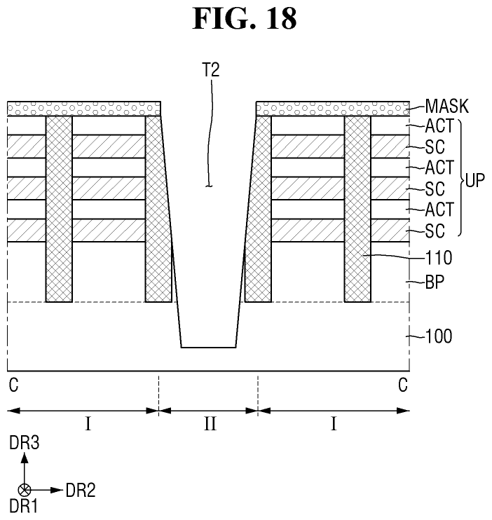

Referring to FIGS. 17 and 18, the second trench T2 may be formed using the mask pattern MASK as a mask.

The second trench T2 may be formed in the dummy region II by removing the exposed upper pattern UP using the mask pattern MASK. The second trench T2 may penetrate the upper pattern UP and the lower pattern BP. For example, a bottom surface of the second trench T2 may be at a lower level than a bottom surface of the lower pattern BP. A portion of the second trench T2 may be formed by etching a portion of the substrate 100. The second trench T2 may extend in the third direction DR3. A portion of the field insulating layer 110 may be removed by the second trench T2.

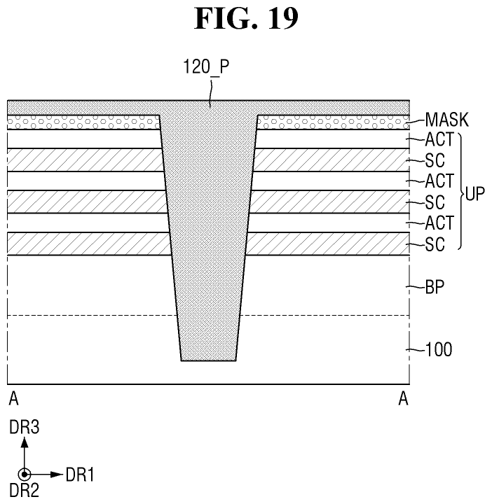

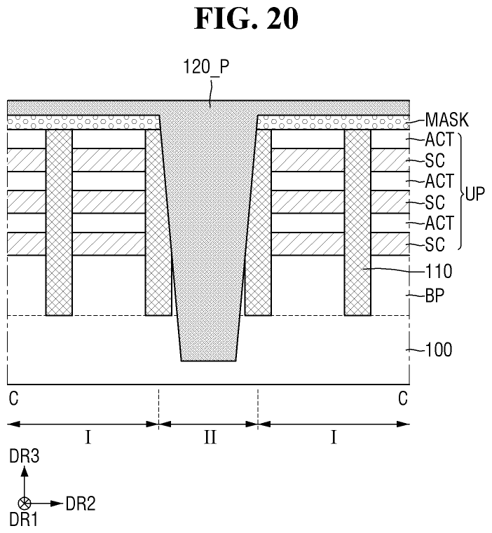

Referring to FIGS. 19 and 20, a pre-buried insulating pattern 120_P may fill the second trench T2.

The upper surface of the mask pattern MASK may be covered by the pre-buried insulating pattern 120_P. The upper surface of the pre-buried insulating pattern 120_P may be higher than the upper surface of the mask pattern MASK.

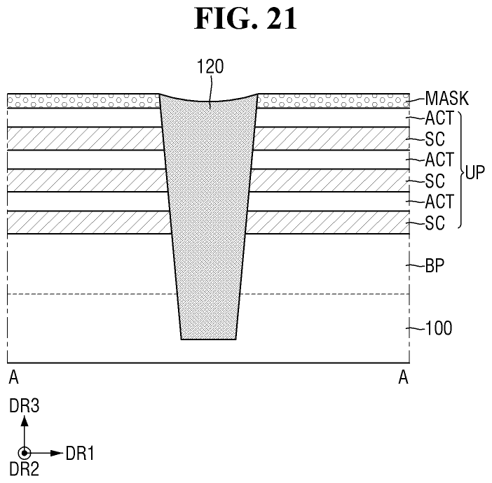

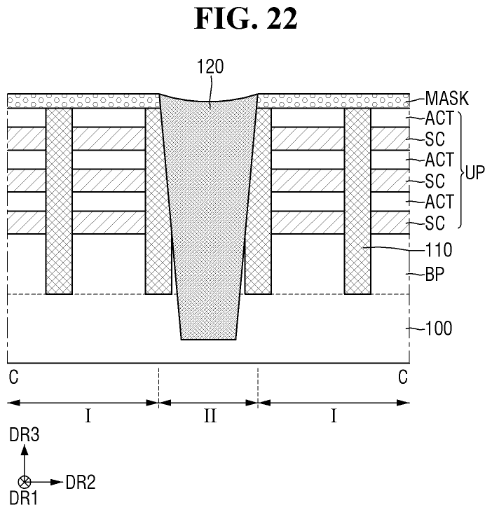

Referring to FIGS. 21 and 22, the buried insulating pattern 120 filling the second trench T2 may be formed.

The pre-buried insulating pattern 120_P may be etched using the mask pattern MASK as an etch stop layer. The pre-buried insulating pattern 120_P formed on the upper surface of the mask pattern MASK may be removed, thereby forming the buried insulating pattern 120. The upper surface of the buried insulating pattern 120 may have a concave shape. The buried insulating pattern 120 may not cover the upper surface of the mask pattern MASK.

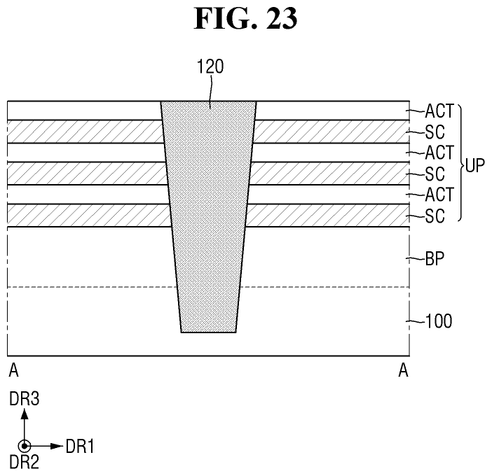

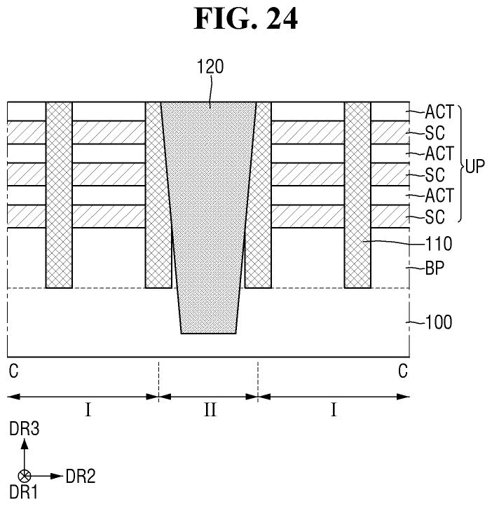

Referring to FIGS. 23 and 24, the mask pattern MASK may be removed using a planarization process.

While the mask pattern MASK is being removed, the upper surface of the buried insulating pattern 120 may be planarized. The mask pattern MASK may be removed to expose the field insulating layer 110 and the uppermost portion of the upper pattern UP.

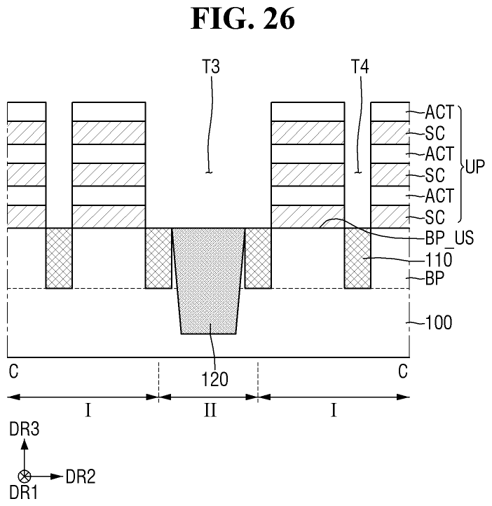

Referring to FIGS. 25 and 26, the field insulating layer 110 and the buried insulating pattern 120 may be recessed.

The field insulating layer 110 and the buried insulating pattern 120 may be recessed to form the third trench T3 and a fourth trench T4. The field insulating layer 110 and the buried insulating pattern 120 may be recessed to the upper surface BP_US of the lower pattern BP. For example, the field insulating layer 110 and the buried insulating pattern 120 may be recessed to a level the same as the upper surface BP_US of the lower pattern BP such that the upper surfaces of the field insulating layer 110, the buried insulating pattern 120 and the lower pattern BP are at the same level. The third trench T3 and the fourth trench T4 may extend in the third direction DR3. The upper surface BP_US of the lower pattern BP and the lower surface of the upper pattern UP may be on the same plane. For example, the upper surface BP_US of the lower pattern BP may contact the lower surface of the upper pattern UP.

The third trench T3 may be formed in the dummy region II. The fourth trench T4 may be formed in the cell region I. The third trench T3 and the fourth trench T4 may be spaced apart from each other in the second direction DR2. The sidewall of the upper pattern UP may be exposed by the third trench T3 and the fourth trench T4.

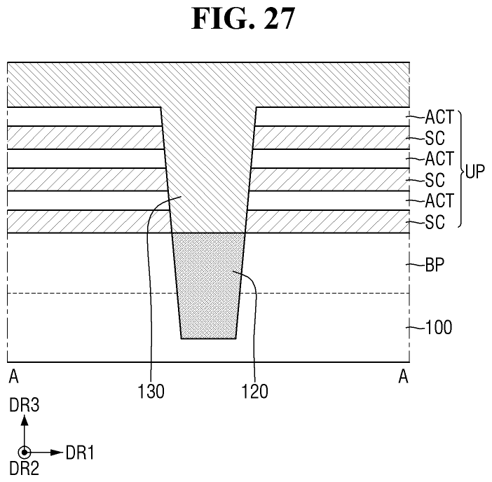

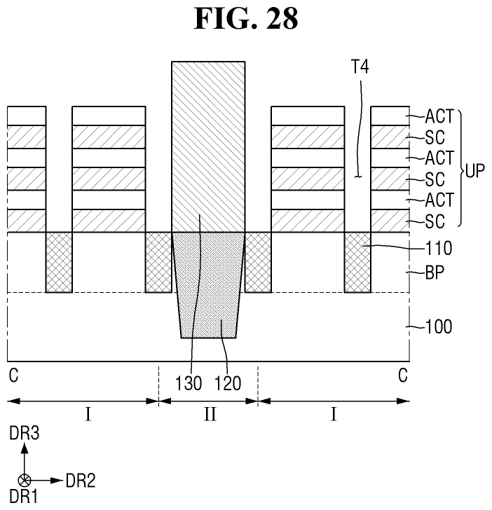

Referring to FIGS. 27 and 28, the dummy blocking layer 130 may be formed on the buried insulating pattern 120. The dummy blocking layer 130 may be formed in the dummy region II.

The dummy blocking layer 130 may not cover the field insulating layer 110. From the upper surface BP_US of the lower pattern BP, a distance to the upper surface of the dummy blocking layer 130 may be greater than a distance to the upper surface of the upper pattern UP existing on the cell region I in the third direction DR3. For example, the upper surface of the dummy blocking layer 130 may be at a higher level than the upper surface of the upper pattern UP.

The dummy blocking layer 130 may be formed to extend (e.g., lengthwise) in the first direction DR1. The dummy blocking layer 130 may cover the upper pattern UP existing/formed in the dummy region II.

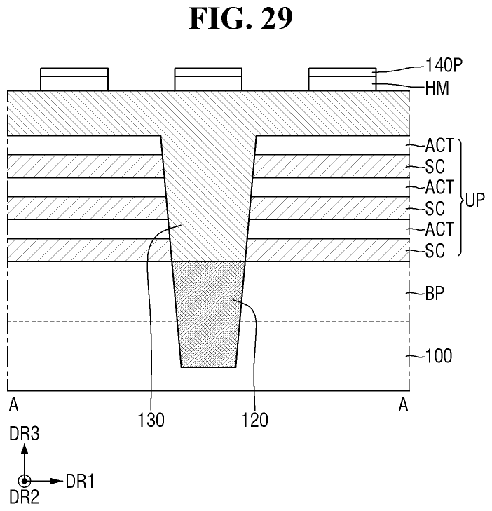

Referring to FIGS. 29 to 31, a dummy gate insulating layer 150, a dummy gate electrode DG, a hard mask pattern HM, and a pre-gate spacer 140P may be formed.

The dummy gate insulating layer 150 may cover the upper surface of the upper pattern UP. The dummy gate insulating layer 150 may not be formed in the dummy region II.

The dummy gate electrode DG may fill the fourth trench T4. The dummy gate electrode DG may fill a portion of the third trench T3 except a portion filled with the dummy blocking layer 130. The dummy gate electrode DG may be in contact with the exposed sidewall of the upper pattern UP and the upper surface of the field insulating layer 110. The dummy gate electrode DG may cover the dummy gate insulating layer 150. The upper surface of the dummy gate electrode DG may be in contact with the lower surface of the hard mask pattern HM.

The hard mask pattern HM may cover the upper surface of the dummy gate electrode DG. A plurality of hard mask patterns HM spaced apart from each other in the first direction DR1 may be formed on the upper surface of the dummy blocking layer 130. The hard mask pattern HM may extend (e.g., lengthwise) in the second direction DR2.

The pre-gate spacer 140P may cover the upper pattern UP, the dummy gate insulating layer 150, the dummy gate electrode DG, and the hard mask pattern HM. The pre-gate spacer 140P may be formed along the upper surface of the upper pattern UP, the sidewall of the dummy gate insulating layer 150, the sidewall of the dummy gate electrode DG, and the upper surface and the sidewall of the hard mask.

Referring to FIG. 32, the source/drain recess 160R may be formed in the upper pattern UP.

The source/drain recess 160R may extend in the third direction DR3. A portion of the source/drain recess 160R may be formed in the lower pattern BP. For example, a bottom surface of the source/drain recess 160R may be at a level lower than a top surface of the lower pattern BP. The source/drain recess 160R may be formed on at least one side of the dummy gate electrode DG. In this case, the thickness of the hard mask may decrease.

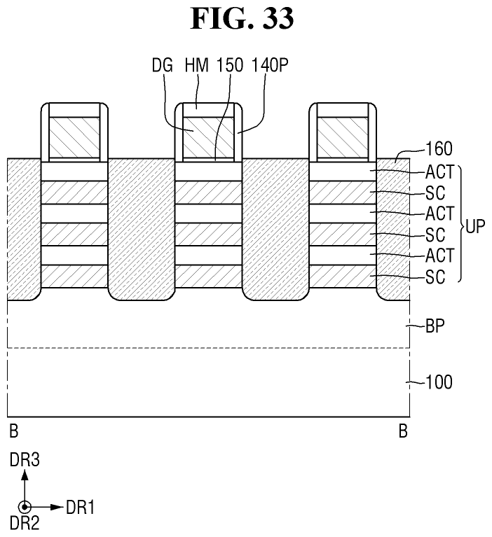

Referring to FIG. 33, the source/drain pattern 160 may be formed in the source/drain recess 160R.

The source/drain pattern 160 may be formed on at least one side of the dummy gate electrode DG.

The source/drain pattern 160 may be formed on the lower pattern BP. For example, the source/drain pattern 160 may contact the lower pattern BP. The source/drain pattern 160 may be in contact with the sacrificial pattern SC and the active pattern ACT.

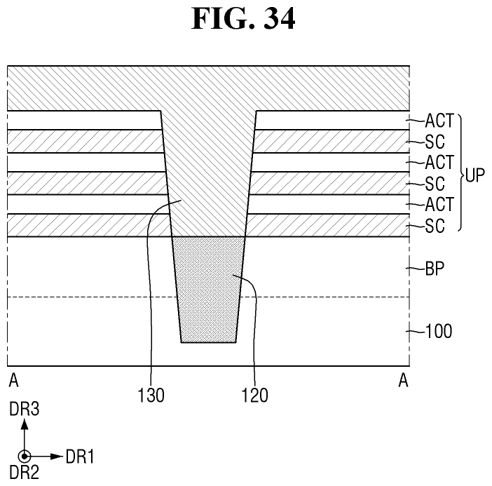

Referring to FIGS. 34 to 36, the first etch stop layer 171 and the first interlayer insulating layer 181 may be formed on the source/drain pattern 160.

While the first interlayer insulating layer 181 is being formed/patterned, the hard mask pattern HM may be removed to expose the upper surface of the dummy gate electrode DG and the gate spacer 140. The upper portion of the pre-gate spacer 140P may be partially etched/removed to form the gate spacer 140 while the first interlayer insulating layer 181 is patterned.

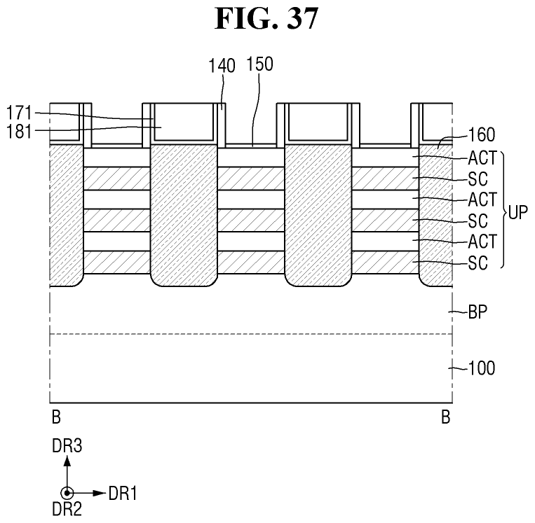

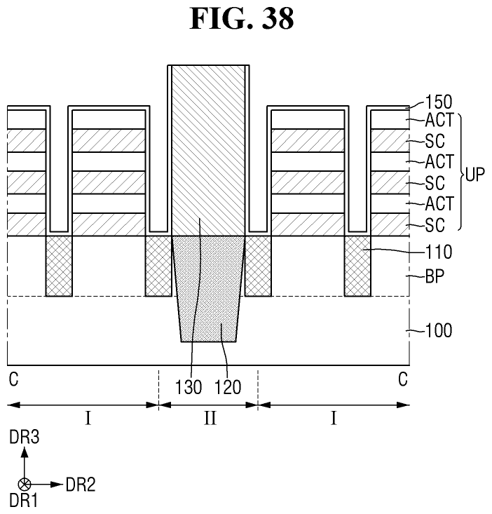

Referring to FIGS. 37 and 38, the dummy gate electrode DG may be removed.

The dummy gate electrode DG may be removed to expose the dummy gate insulating layer 150.

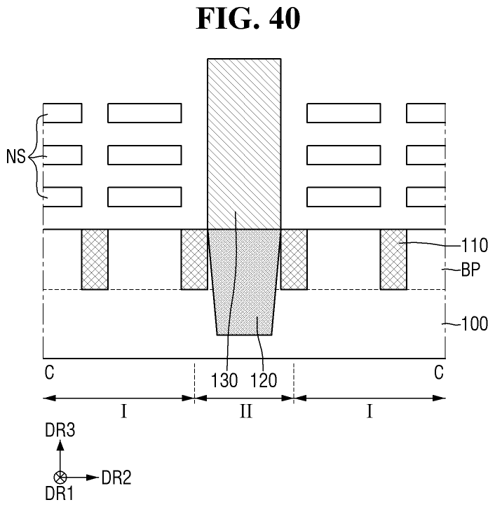

Referring to FIGS. 39 and 40, after the dummy gate insulating layer 150 is removed, the sacrificial pattern SC may be removed.

The sacrificial pattern SC may be removed to form the sheet pattern NS. An empty space may exist between neighboring sheet patterns NS. Neighboring sheet patterns NS may be spaced apart from each other in the third direction DR3.

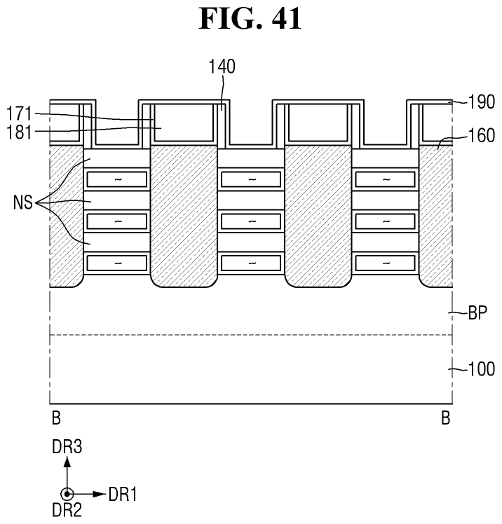

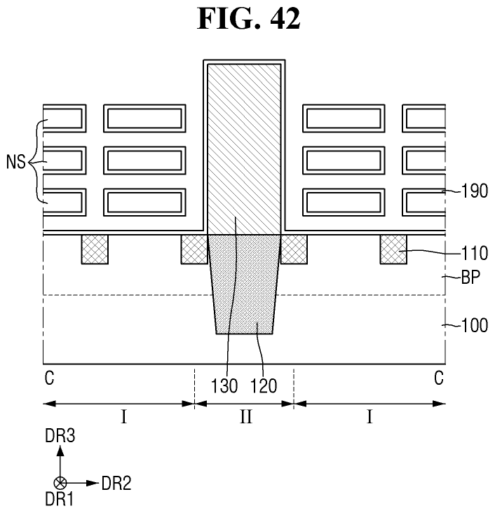

Referring to FIGS. 41 and 42, the gate insulating layer 190 may be formed on the gate spacer 140, the first etch stop layer 171, the first interlayer insulating layer 181, and the dummy blocking layer 130.

The gate insulating layer 190 may surround the sheet pattern NS. The gate insulating layer 190 may be formed on the exposed upper surface BP_US of the lower pattern BP. The gate insulating layer 190 may be formed on the sidewall and the upper surface of the dummy blocking layer 130.

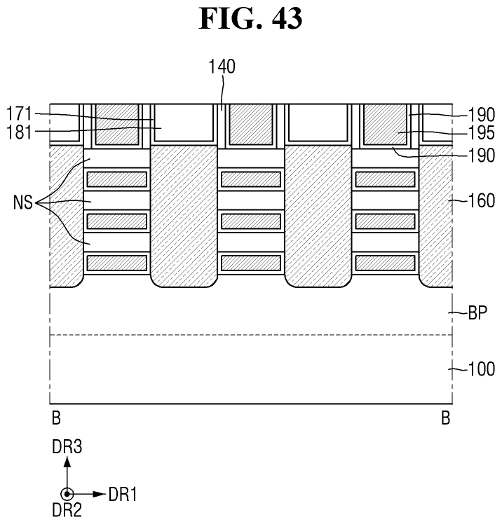

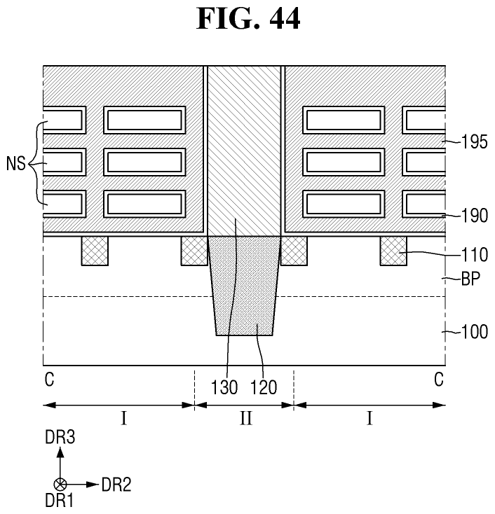

Referring to FIGS. 43 and 44, the gate electrode 195 surrounding the sheet pattern NS may be formed.

The gate electrode 195 may fill the empty space between neighboring sheet patterns NS. The gate electrode 195 may fill the remaining portion of the fourth trench T4 except the portion filled by the gate insulating layer 190. The gate insulating layer 190 surrounding the upper surface of the dummy blocking layer 130 may be removed. The upper surface of the gate electrode 195 and the uppermost portion of the gate spacer 140 may be on the same plane. For example, a top surface of the gate electrode 195 and a top surface of the gate spacer 140 may be at the same level.

In some embodiments, the processes of FIGS. 2, 3, and 5 may proceed at the same time. In some other embodiments, the processes of FIGS. 2, 4 and 5 may proceed at the same time. However, the disclosure is not limited thereto. For example, the semiconductor device may be manufactured by other processes different from the ones shown in the above embodiments.

Referring back to FIG. 2, the second etch stop layer 172, the second interlayer insulating layer 182, the third etch stop layer 173, and the third interlayer insulating layer 183 may be sequentially stacked on the dummy blocking layer 130.

Next, the lower surface 100_BS of the substrate 100 may be etched. The lower surface 100_BS of the substrate 100 may be etched until the lower surface 100_BS of the substrate 100 and the lower surface of the buried insulating pattern 120 are located on the same plane.

Next, the backside wiring insulating layer 210 may be formed on the lower surface 100_BS of the substrate 100.

Referring back to FIGS. 3 and 5, the gate capping layer 200 may be formed. The gate capping layer 200 may be formed on the gate spacer 140, the gate electrode 195, and the gate insulating layer 190. The upper surface of the gate capping layer 200 may be on the same plane (e.g., at the same level) as the upper surface of the first interlayer insulating layer 181. Further, the upper surface of the gate capping layer 200 may be on the same plane (e.g., at the same level) as the upper surface of the first etch stop layer 171. The gate capping layer 200 may not be formed on the dummy blocking layer 130. For example, the gate capping layer 200 may not vertically overlap the dummy blocking layer 130.

Next, the first source/drain contact PSD1 and the second source/drain contact PSD2 may be formed. The first source/drain contact PSD1 and the second source/drain contact PSD2 may penetrate the first interlayer insulating layer 181 and the first etch stop layer 171. The upper surface of the source/drain pattern 160 may be partially recessed by the first source/drain contact PSD1 and/or the second source/drain contact PSD2. The first source/drain contact PSD1 or the second source/drain contact PSD2 may be disposed in the source/drain pattern 160. For example, a bottom surface of the first source/drain contact PSD1 and/or a bottom surface of the second source/drain contact PSD2 may be at a lower level than a top surface of the source/drain pattern 160.

The upper surfaces of the first source/drain contact PSD1 and the second source/drain contact PSD2 may be on the same plane (e.g., at the same level). The upper surfaces of the first source/drain contact PSD1 and the second source/drain contact PSD2 may be on the same plane (e.g., at the same level) as the upper surface of the gate capping layer 200.

Next, the second etch stop layer 172 and the second interlayer insulating layer 182 may be sequentially stacked on the upper surfaces of the gate capping layer 200, the first etch stop layer 171, the first interlayer insulating layer 181, the source/drain pattern 160, and the dummy blocking layer 130.

Next, the front wiring via VF may be formed. The front wiring via VF may penetrate the second interlayer insulating layer 182 and the second etch stop layer 172. The front wiring via VF may be connected to the first source/drain contact PSD1. For example, the lower surface of the front wiring via VF and the upper surface of the first source/drain contact PSD1 may be connected to (e.g., contact) each other.

Next, the third etch stop layer 173 and the third interlayer insulating layer 183 may be sequentially stacked on the upper surface of the second interlayer insulating layer 182 and the upper surface of the first source/drain contact PSD1.

Next, the front wiring plug PF may be formed. The front wiring plug PF may penetrate the third etch stop layer 173 and the third interlayer insulating layer 183. The front wiring plug PF may be connected to the front wiring via VF. More specifically, the lower surface of the front wiring plug PF and the upper surface of the front wiring via VF may be connected to each other.

Next, the lower surface 100_BS of the substrate 100 may be etched. The lower surface 100_BS of the substrate 100 may be etched until the lower surface 100_BS of the substrate 100 and the lower surface of the buried insulating pattern 120 are located on the same plane.

Next, the backside wiring insulating layer 210 may be formed on the lower surface 100_BS of the substrate 100.

Next, the first backside wiring line 215 and the second backside wiring line 216 may be formed in the backside wiring insulating layer 210 of the substrate 100. The first backside wiring line 215 and the second backside wiring line 216 may be spaced apart from each other in the second direction DR2. The first backside wiring line 215 and the second backside wiring line 216 may extend in the first direction DR1.

Referring back to FIGS. 4 and 5, the gate capping layer 200 may be formed. The gate capping layer 200 may be formed on the gate spacer 140, the gate electrode 195, and the gate insulating layer 190. The upper surface of the gate capping layer 200 may be on the same plane as the upper surface of the first interlayer insulating layer 181. Further, the upper surface of the gate capping layer 200 may be on the same plane as the upper surface of the first etch stop layer 171. The gate capping layer 200 may not be formed on the dummy blocking layer 130.

Next, the first source/drain contact PSD1 may be formed. The first source/drain contact PSD1 may penetrate the first interlayer insulating layer 181 and the first etch stop layer 171. The upper surface of the source/drain pattern 160 may be partially recessed by the first source/drain contact PSD1. The first source/drain contact PSD1 may be disposed in the source/drain pattern 160.

The upper surface of the first source/drain contact PSD1 may be on the same plane as the upper surface of the gate capping layer 200.

Next, the second etch stop layer 172 and the second interlayer insulating layer 182 may be sequentially stacked on the upper surfaces of the gate capping layer 200, the first etch stop layer 171, the first interlayer insulating layer 181, the source/drain pattern 160, and the dummy blocking layer 130.

Next, the front wiring via VF may be formed. The front wiring via VF may penetrate the second interlayer insulating layer 182 and the second etch stop layer 172. The front wiring via VF may be electrically connected to (e.g., contact) the first source/drain contact PSD1. For example, the lower/bottom surface of the front wiring via VF and the upper/top surface of the first source/drain contact PSD1 may be connected to (e.g., contact) each other.

Next, the third etch stop layer 173 and the third interlayer insulating layer 183 may be sequentially stacked on the upper surface of the second interlayer insulating layer 182 and the upper surface of the first source/drain contact PSD1.

Next, the front wiring plug PF may be formed. The front wiring plug PF may penetrate the third etch stop layer 173 and the third interlayer insulating layer 183. The front wiring plug PF may be electrically connected to (e.g., contact) the front wiring via VF. For example, the lower/bottom surface of the front wiring plug PF and the upper/top surface of the front wiring via VF may be connected to (e.g., contact) each other.

Next, the third source/drain contact PSD3 may be formed. The third source/drain contact PSD3 may penetrate the substrate 100 and the lower pattern BP. The lower/bottom surface of the source/drain pattern 160 may be partially recessed by the third source/drain contact PSD3. The third source/drain contact PSD3 may be disposed in the source/drain pattern 160. For example, a top surface of the third source/drain contact PSD3 may be at a level higher than a level of the bottom surface of the source/drain pattern 160.

Next, the lower surface 100_BS of the substrate 100 may be etched. The lower surface 100_BS of the substrate 100 may be etched until the lower surface 100_BS of the substrate 100 and the lower surface of the buried insulating pattern 120 are located on the same plane. At the same time, the lower portion of the third source/drain contact PSD3 may be etched. The lower surface of the third source/drain contact PSD3 and the lower surface 100_BS of the substrate 100 may be on the same plane.

Next, the backside wiring insulating layer 210 may be formed on the lower surface 100_BS of the substrate 100.

Next, the first backside wiring line 215 and the second backside wiring line 216 may be formed in the backside wiring insulating layer 210 on the substrate 100. The first backside wiring line 215 and the second backside wiring line 216 may be spaced apart from each other in the second direction DR2. The first backside wiring line 215 and the second backside wiring line 216 may extend (e.g., lengthwise) in the first direction DR1.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor device comprising:
a substrate comprising cell regions, a dummy region between the cell regions, an upper surface and a lower surface opposite the upper surface in a first direction;
an active pattern disposed on the upper surface of the substrate, the active pattern comprising a lower pattern extending in a second direction crossing the first direction and a plurality of sheet patterns spaced apart from each other in the first direction, the plurality of sheet patterns being disposed in the cell region;
a plurality of gate structures spaced apart from each other in the second direction on the lower pattern, the plurality of gate structures comprising a gate electrode and a gate insulating layer, the gate electrode and the gate insulating layer surrounding the sheet patterns;
a source/drain pattern disposed between the gate structures adjacent to each other; and
a buried insulating pattern penetrating the substrate and the lower pattern in the dummy region,
wherein the buried insulating pattern comprises a first surface and a second surface opposite to each other in the first direction,
the first surface of the buried insulating pattern is placed on the same plane as the lower surface of the substrate, and
the second surface of the buried insulating pattern is higher than the upper surface of the substrate.

2. The semiconductor device of claim 1, wherein the active pattern and the gate structures are not disposed on the dummy region.

3. The semiconductor device of claim 2, further comprising a field insulating layer between two lower patterns adjacent to each other.

4. The semiconductor device of claim 3, wherein an upper surface of the field insulating layer and an upper surface of the buried insulating pattern are on the same plane.

5. The semiconductor device of claim 1, wherein the source/drain pattern comprises a source/drain blocking layer and a source/drain filling layer disposed on the source/drain blocking layer.

6. The semiconductor device of claim 1, further comprising a backside wiring line disposed on the lower surface of the substrate.

7. The semiconductor device of claim 6, further comprising a source/drain contact disposed on the upper surface of the substrate, and electrically connected to the source/drain pattern.

8. The semiconductor device of claim 7, further comprising:
a front wiring via electrically connected to the source/drain contact; and
a front wiring plug electrically connected to the front wiring via.

9. The semiconductor device of claim 6, further comprising a source/drain contact penetrating the substrate and disposed between the backside wiring line and the source/drain pattern.

10. A semiconductor device comprising:
a substrate comprising a cell region, a dummy region adjacent to the cell region, an upper surface and a lower surface opposite the upper surface in a first direction;
an active pattern disposed on the upper surface of the substrate, the active pattern comprising a lower pattern extending in a second direction crossing the first direction and a plurality of sheet patterns spaced apart from each other in the first direction, the plurality of sheet patterns being disposed in the cell region;
a plurality of gate structures spaced apart from each other in the second direction on the lower pattern, the plurality of gate structures comprising a gate electrode and a gate insulating layer, the gate electrode and the gate insulating layer surrounding the sheet patterns;
a source/drain pattern disposed between the gate structures adjacent to each other; and
a buried insulating pattern penetrating the substrate and the lower pattern in the dummy region,
wherein the buried insulating pattern comprises a first surface and a second surface opposite to each other in the first direction,
the first surface of the buried insulating pattern is on the same plane as the lower surface of the substrate, and
the second surface of the buried insulating pattern is higher than the upper surface of the substrate.

11. The semiconductor device of claim 10, wherein the active pattern and the gate structures are not disposed on the dummy region.

12. The semiconductor device of claim 11, further comprising a field insulating layer between lower patterns adjacent to each other.

13. The semiconductor device of claim 12, wherein an upper surface of the field insulating layer and an upper surface of the buried insulating pattern are on the same plane.

14. The semiconductor device of claim 10, wherein the source/drain pattern comprises a source/drain blocking layer and a source/drain filling layer disposed on the source/drain blocking layer.

15. The semiconductor device of claim 10, further comprising a backside wiring line disposed on the lower surface of the substrate.

16. The semiconductor device of claim 15, further comprising a source/drain contact disposed on the upper surface of the substrate, and electrically connected to the source/drain pattern.

17. The semiconductor device of claim 16, further comprising:
a front wiring via electrically connected to the source/drain contact; and
a front wiring plug electrically connected to the front wiring via.

18. The semiconductor device of claim 15, further comprising a source/drain contact penetrating the substrate and disposed between the backside wiring line and the source/drain pattern.

19. A method for manufacturing a semiconductor device, comprising:
providing a substrate comprising a cell region and a dummy region;
forming a lower pattern on an upper surface of the substrate;
forming an upper pattern comprising sacrificial patterns and active patterns alternately disposed on an upper surface of the lower pattern;
forming a trench penetrating the lower pattern and the upper pattern;
filling the trench with a field insulating layer;
forming a mask pattern on the upper pattern;
forming a buried insulating pattern penetrating the mask pattern, the upper pattern, and the lower pattern in the dummy region, a lower surface of the buried insulating pattern being lower than the upper surface of the substrate, and an upper surface of the buried insulating pattern and an upper surface of the upper pattern being disposed on the same plane; and
recessing the buried insulating pattern to form a buried pattern up to the same plane as the upper surface of the lower pattern.

20. The method of claim 19, further comprising removing a portion of the substrate using a planarization process,
wherein the lower surface of the buried insulating pattern is placed on the same plane as a lower surface of the substrate.
